(19) United States
(12) Patent Application Publication
(10) Pub. No.: US 2025/0022916 A1
(43) Pub. Date: Jan. 16, 2025

(54) SIC SEMICONDUCTOR DEVICE

(71) Applicant: ROHM CO., LTD., Kyoto-shi (JP)

(72) Inventors: Keisuke NAGAYA, Kyoto-shi (JP); Yuki NAKANO, Kyoto-shi (JP); Kenji YAMAMOTO, Kyoto-shi (JP); Seigo MORI, Kyoto-shi (JP)

(73) Assignee: ROHM CO., LTD., Kyoto-shi (JP)

(21) Appl. No.: 18/900,918

(22) Filed: Sep. 30, 2024

Related U.S. Application Data
(63) Continuation of application No. PCT/JP2023/006637, filed on Feb. 24, 2023.

(30) Foreign Application Priority Data
Mar. 31, 2022 (JP) 2022-061146

(51) Int. Cl. H01L 29/06; H01L 27/088; H01L 29/04; H01L 29/16; H01L 29/739; H01L 29/78

(52) U.S. Cl. CPC H01L 29/0696; H01L 27/088; H01L 29/7397; H01L 29/7813; H01L 29/045; H01L 29/1608

(57) ABSTRACT

An SiC semiconductor device comprises: a chip that includes an SiC monocrystal and has a main surface; a trench structure that has a first side wall extending in an a-axis direction of the SiC monocrystal and a second side wall extending in an m-axis direction of the SiC monocrystal and is formed in the main surface; and a contact region of a first conductivity type that is formed in a region inside the chip along the trench structure at an interval in the m-axis direction from the first side wall.

### CROSS-REFERENCE TO RELATED APPLICATIONS

The present application is a bypass continuation of International Patent Application No. PCT/JP2023/006637 filed on Feb. 24, 2023, claiming the benefit of priority based on Japanese Patent Application No. 2022-061146 filed on Mar. 31, 2022, and the entire disclosures of those applications are hereby incorporated herein by reference.

### BACKGROUND

### 1. Field of the Disclosure

The present disclosure relates to an SiC semiconductor device.

### 2. Description of the Related Art

US2014/0145209A1 discloses, in FIG. 8, an SiC vertical power MOSFET that includes an n-type drift layer, a trench structure formed in the n-type drift layer, and a high-concentration p base region formed in a region inside the n-type drift layer along a bottom wall of the trench structure.

### BRIEF DESCRIPTION OF THE DRAWINGS

FIG. 1 is a plan view showing an SiC semiconductor device according to a first embodiment.

FIG. 2 is a plan view showing a layout of a first main surface.

FIG. 3 is a cross sectional view taken along line III-III shown in FIG. 2.

FIG. 4 is an enlarged plan view showing a main portion of the first main surface.

FIG. 5 is an enlarged plan view showing another main portion of the first main surface.

FIG. 6 is a cross sectional view taken along line VI-VI shown in FIG. 4.

FIG. 7 is a cross sectional view taken along line VII-VII shown in FIG. 5.

FIG. 8 is an enlarged plan view showing a region including second trench structures and a third trench structure.

FIG. 9 is a cross sectional view taken along line IX-IX shown in FIG. 8.

FIG. 10 is a cross sectional view taken along line X-X shown in FIG. 8.

FIG. 11 is a cross sectional view taken along line XI-XI shown in FIG. 8.

FIG. 12 is a cross sectional view taken along line XII-XII shown in FIG. 8.

FIG. 13 is a cross sectional view taken along line XIII-XIII shown in FIG. 8.

FIG. 14 is a cross sectional view taken along line XIV-XIV shown in FIG. 8.

FIG. 15 is a cross sectional view taken along line XV-XV shown in FIG. 8.

FIG. 16 is a cross sectional view showing a peripheral edge portion of a chip.

FIG. 17 is a plan view showing an SiC semiconductor device according to a second embodiment.

FIG. 18 is a cross sectional view taken along line XVIII-XVIII shown in FIG. 17.

FIG. 19 is a plan view showing an SiC semiconductor device according to a third embodiment.

FIG. 20 is a plan view showing an SiC semiconductor device according to a fourth embodiment.

FIG. 21 is a plan view showing an SiC semiconductor device according to a fifth embodiment.

FIG. 22 is a plan view showing an SiC semiconductor device according to a sixth embodiment.

FIG. 23 is a cross sectional view taken along line XXIII-XXIII shown in FIG. 22.

FIG. 24 is a cross sectional view taken along line XXIV-XXIV shown in FIG. 22.

FIG. 25 is a plan view showing an SiC semiconductor device according to a seventh embodiment.

FIG. 26 is a plan view showing an SiC semiconductor device according to an eighth embodiment.

FIG. 27 is a plan view showing an SiC semiconductor device according to a ninth embodiment.

FIG. 28 is a plan view showing an sic semiconductor device according to a tenth embodiment.

FIG. 29 is a cross sectional view showing a modification example of the second trench structures.

### DETAILED DESCRIPTION OF THE PREFERRED EMBODIMENTS

Hereinafter, embodiments shall be described in detail with reference to attached drawings. The attached drawings are schematic views and are not strictly illustrated, and scales and the like thereof do not always match. Also, identical reference signs are given to corresponding structures among the attached drawings, and duplicate descriptions thereof shall be omitted or simplified. For the structures whose description has been omitted or simplified, the description given before the omission or simplification shall apply.

When the wording “substantially equal” is used in a description in which a comparison target is present, the wording includes a numerical value (form) equal to a numerical value (form) of the comparison target and also includes numerical errors (form errors) in a range of +10% on a basis of the numerical value (form) of the comparison target. Although the wordings “first,” “second,” “third,” etc., are used with the embodiments, these are symbols attached to names of respective structures in order to clarify the order of description and are not attached with an intention of restricting the names of the respective structures.

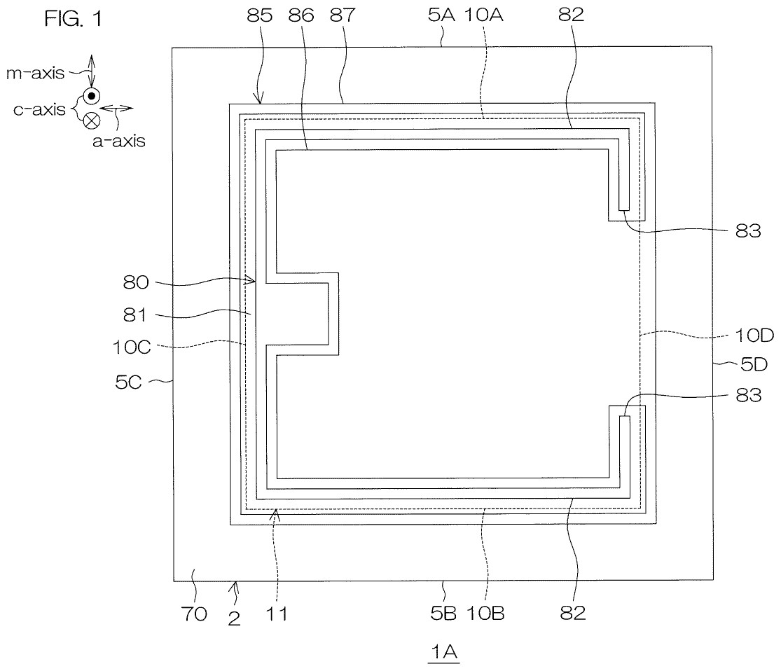

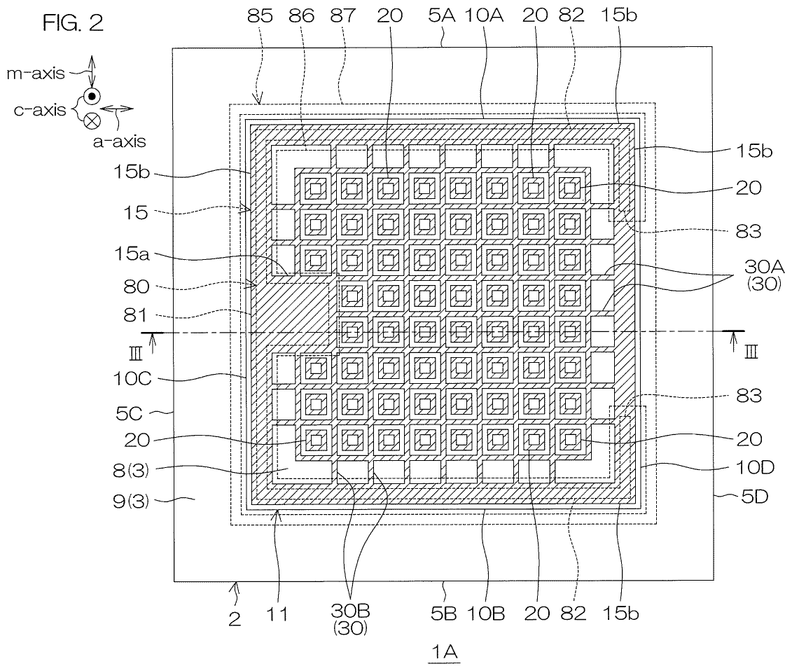

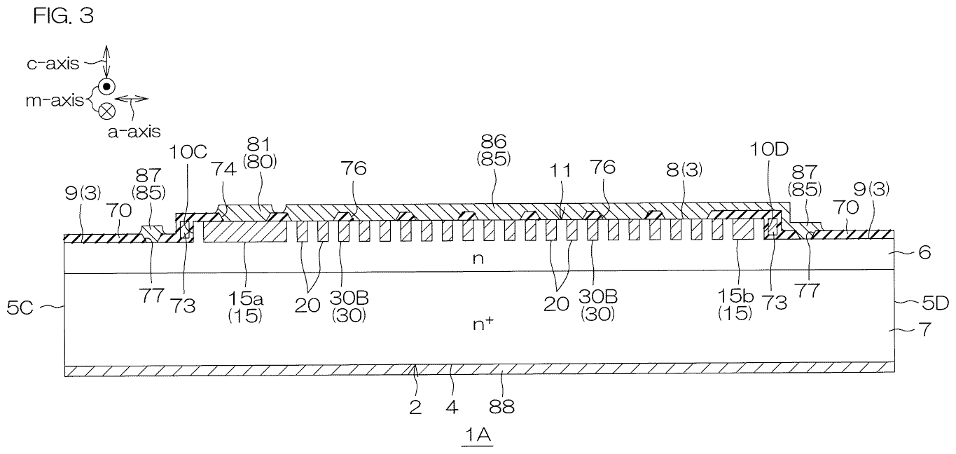

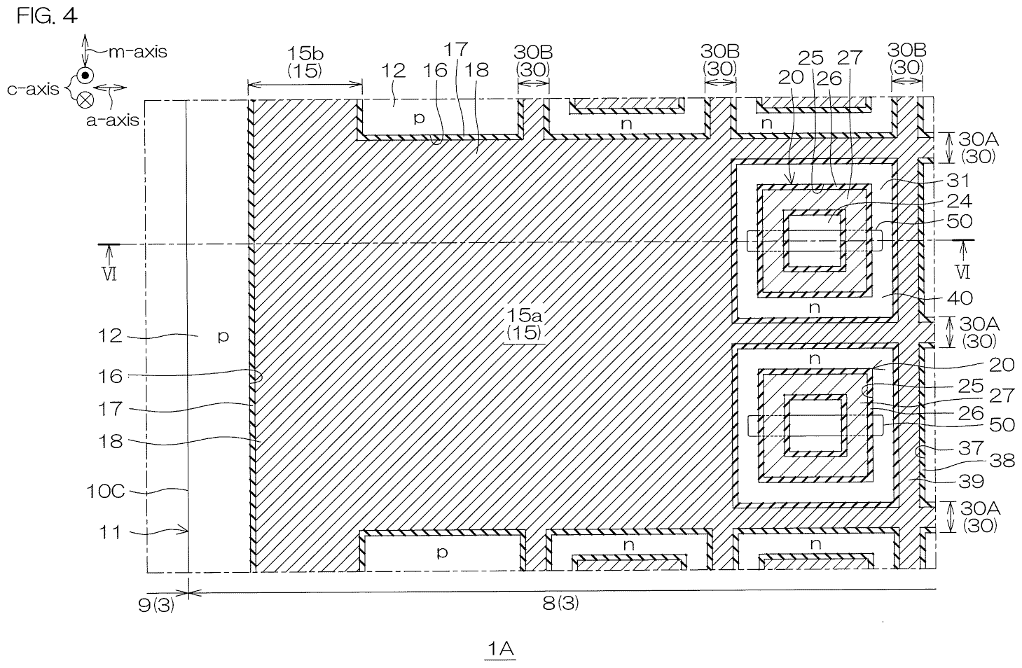

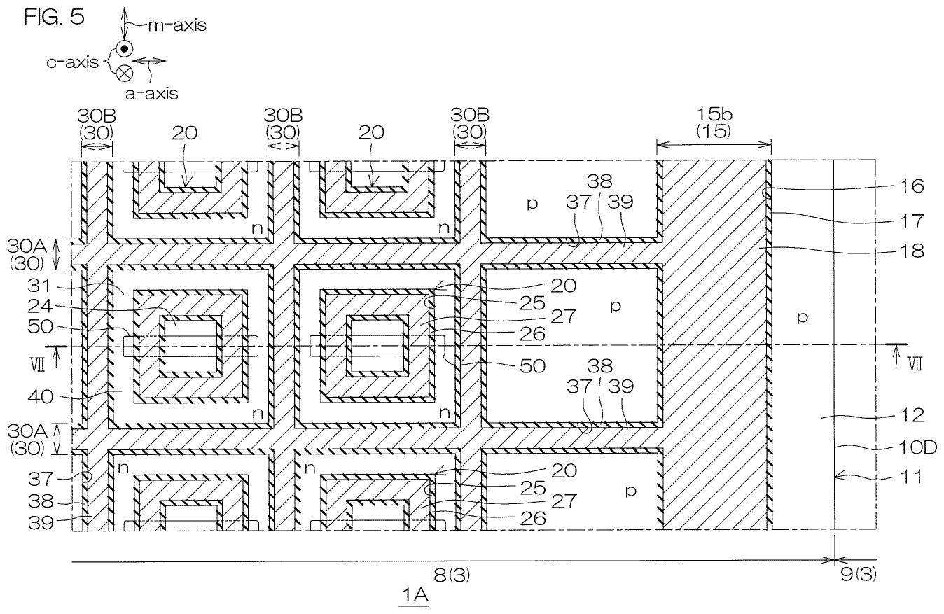

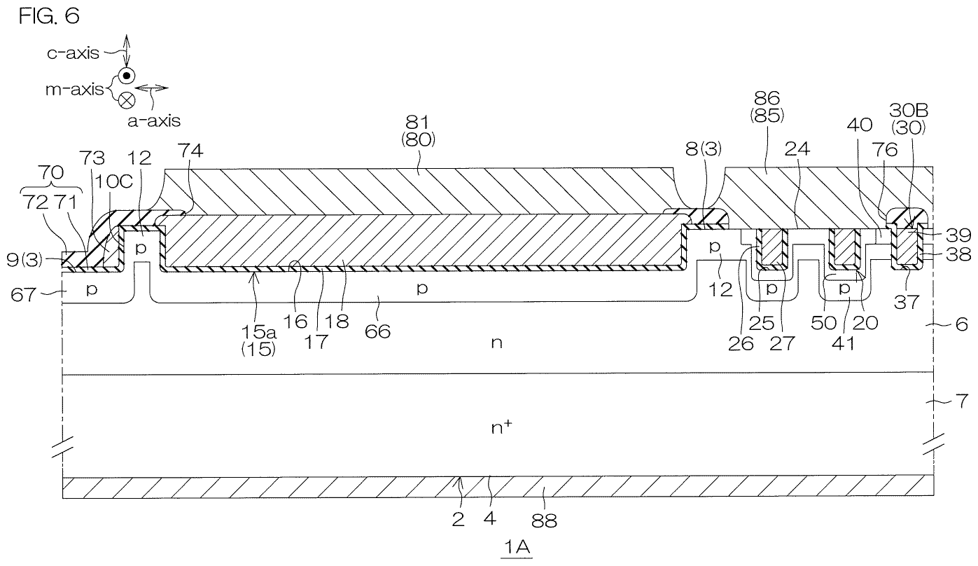

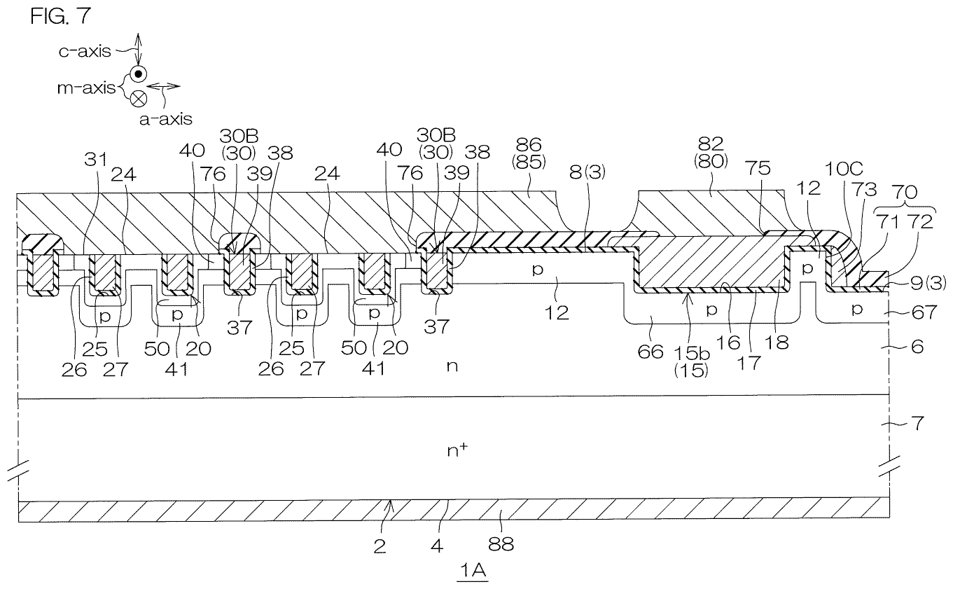

FIG. 1 is a plan view showing an SiC semiconductor device 1A according to a first embodiment. FIG. 2 is a plan view showing a layout of a first main surface 3. FIG. 3 is a cross sectional view taken along line III-III shown in FIG. 2. FIG. 4 is an enlarged plan view showing a main portion of the first main surface 3. FIG. 5 is an enlarged plan view showing another main portion of the first main surface 3. FIG. 6 is a cross sectional view taken along line VI-VI shown in FIG. 4. FIG. 7 is a cross sectional view taken along line VII-VII shown in FIG. 5.

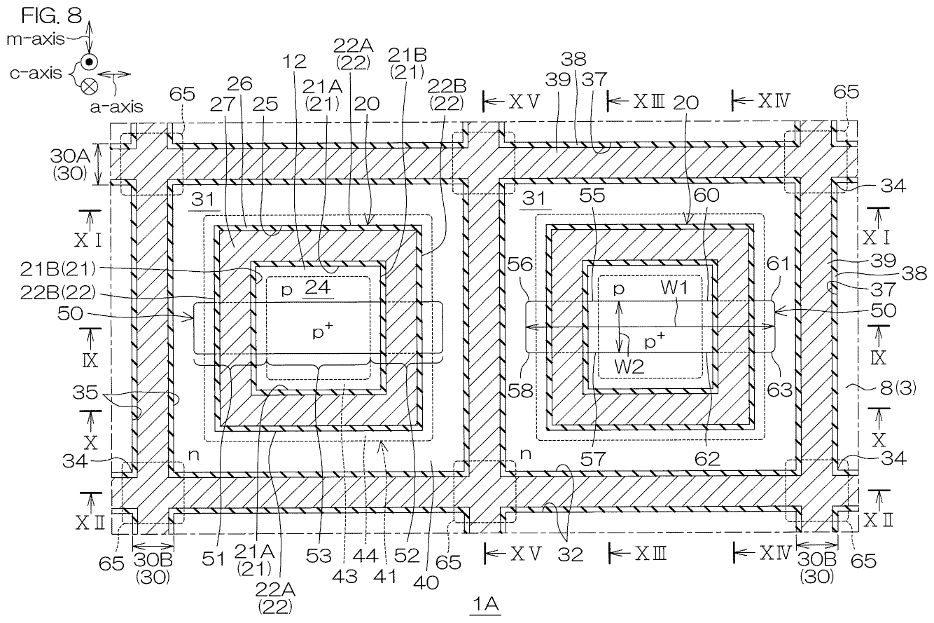

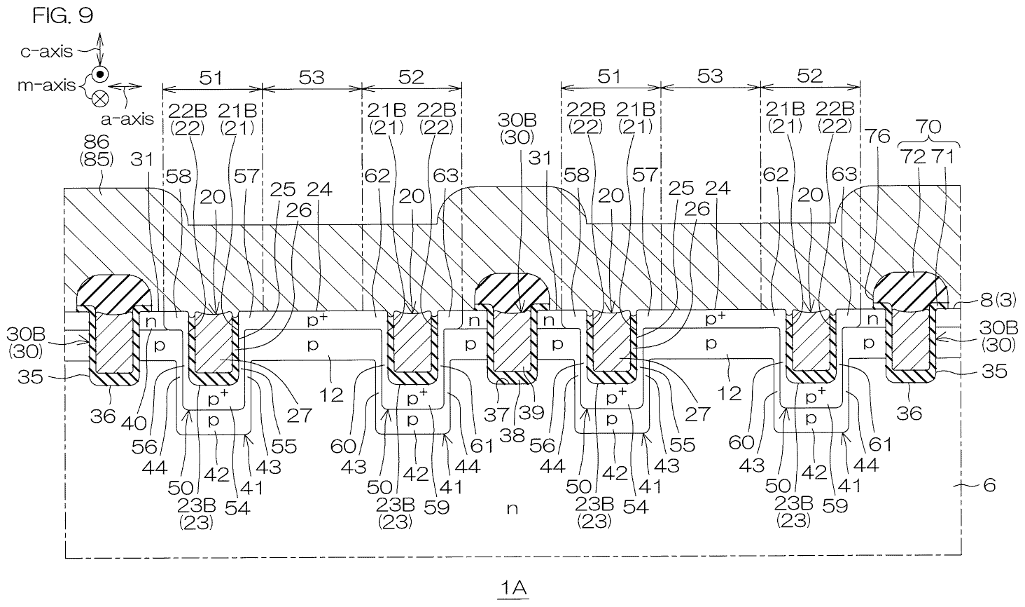

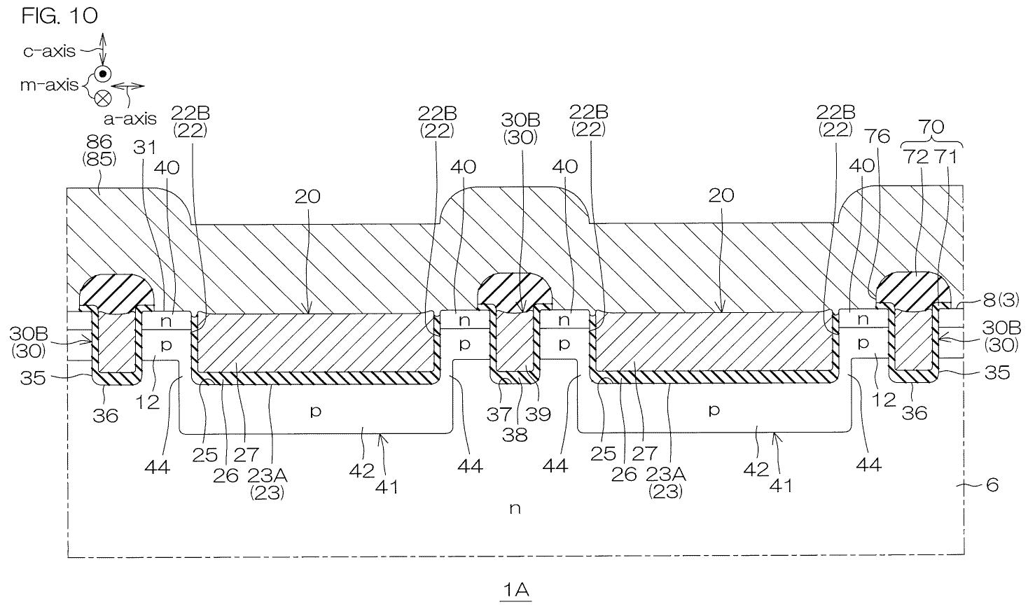

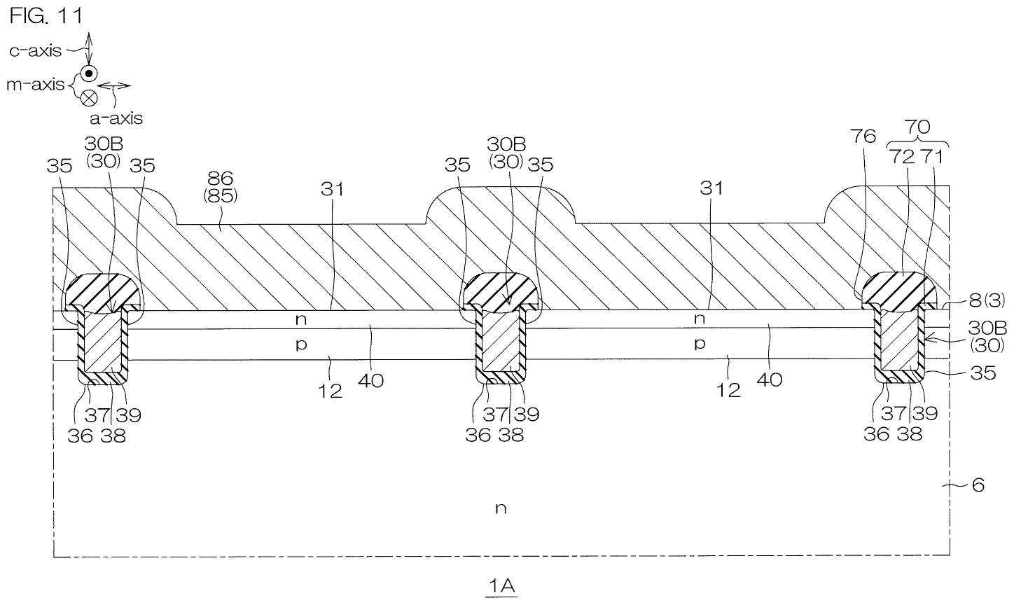

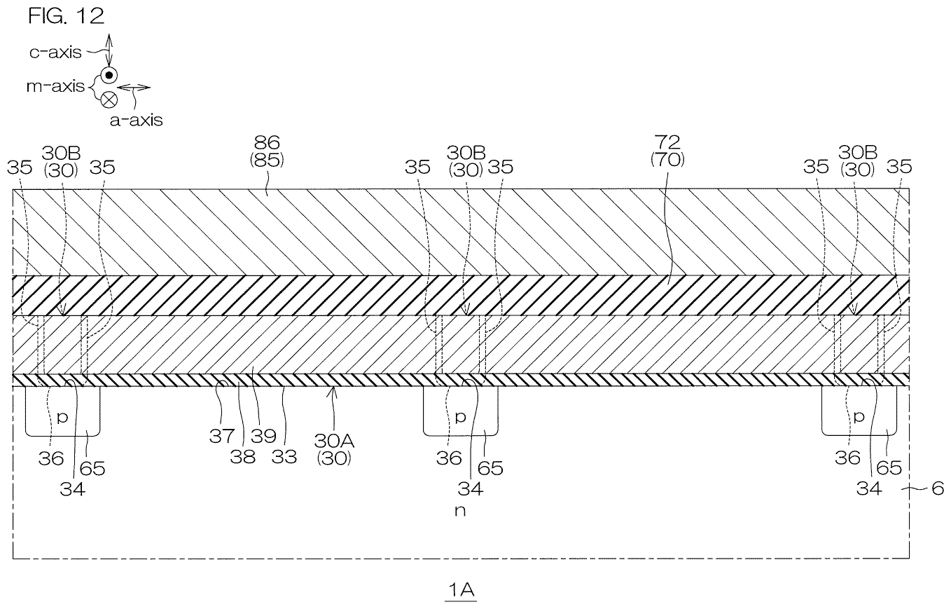

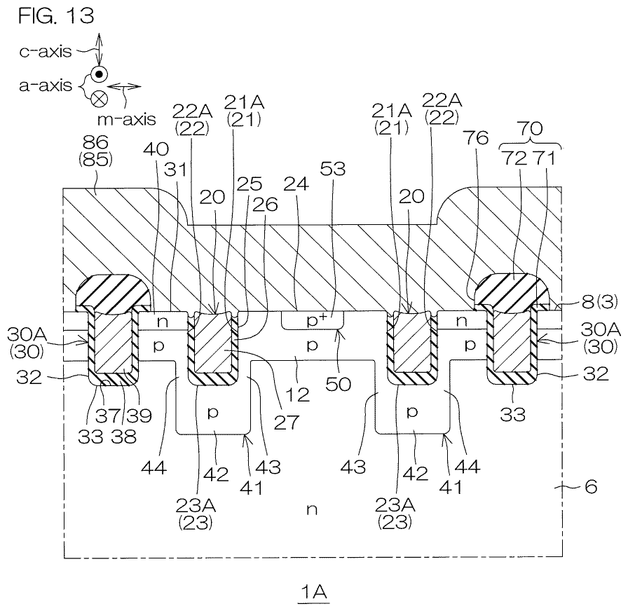

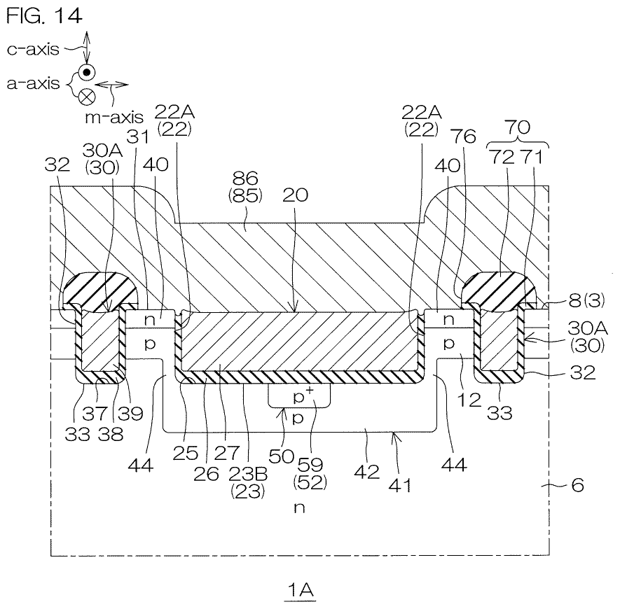

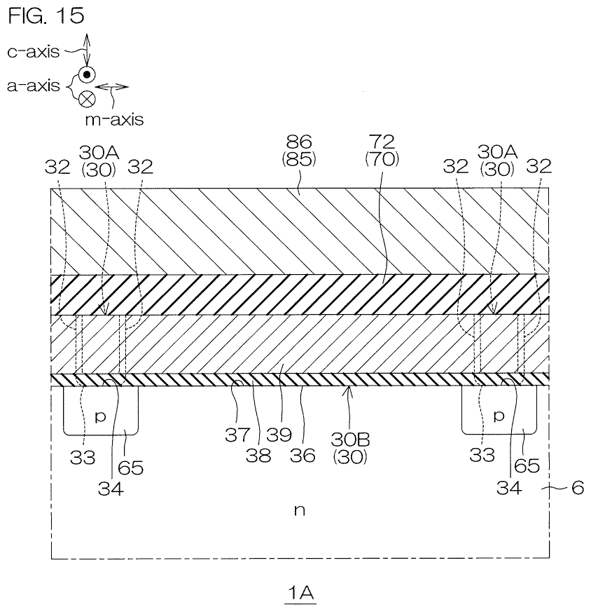

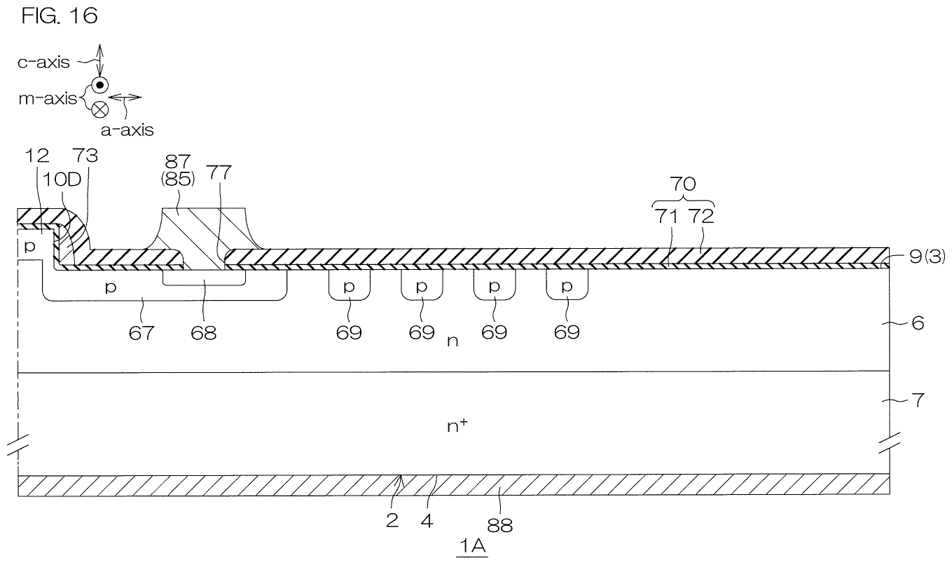

FIG. 8 is an enlarged plan view showing a region including second trench structures 20 and a third trench structure 30. FIG. 9 is a cross sectional view taken along line IX-IX shown in FIG. 8. FIG. 10 is a cross sectional view taken along line X-X shown in FIG. 8. FIG. 11 is a cross sectional view taken along line XI-XI shown in FIG. 8. FIG. 12 is a cross sectional view taken along line XII-XII shown in FIG. 8. FIG. 13 is a cross sectional view taken along line XIII-XIII shown in FIG. 8. FIG. 14 is a cross sectional view taken along line XIV-XIV shown in FIG. 8. FIG. 15 is a cross sectional view taken along line XV-XV shown in FIG. 8. FIG. 16 is a cross sectional view showing a peripheral edge portion of a chip 2.

With reference to FIG. 1 to FIG. 16, the SiC semiconductor device 1A is an SiC semiconductor switching device that includes an SiC-MISFET (metal insulator semiconductor field effect transistor). In this embodiment, the SiC semiconductor device 1A includes the chip 2 including an SiC monocrystal that is a hexagonal crystal and formed in a hexahedral shape (specifically, a rectangular parallelepiped shape). The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 includes the 4H-SiC monocrystal is to be given, but the chip 2 may include another polytype instead.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are formed by c-planes of the SiC monocrystal. Specifically, the first main surface 3 is formed by a silicon plane ((0001) plane) of the SiC monocrystal and the second main surface 4 is formed by a carbon plane ((000-1) plane) of the SiC monocrystal.

The first main surface 3 and the second main surface 4 are each formed in a quadrangle shape in plan view as viewed from a c-axis direction (direction) of the SiC monocrystal (hereinafter, simply referred to as “plan view”). The c-axis direction is a normal direction of the c-plane. The c-axis direction is also a thickness direction of the chip 2. The first main surface 3 and the second main surface 4 may each have an off angle inclined in a predetermined off direction at a predetermined angle with respect to the c-plane.

The off direction is preferably an a-axis direction ([11-20] direction) of the SiC monocrystal. The off angle may exceed 0° and be not more than 10°. The off angle is preferably not more than 5°. When the first main surface 3 (second main surface 4) has the off angle, the c-axis is inclined by just the off angle in the off direction with respect to a normal to the first main surface 3 (second main surface 4). In the attached drawings, the c-axis that extends along the normal to the first main surface 3 (second main surface 4) is illustrated for convenience. The second main surface 4 may consist of a ground surface with grinding marks, or may consist of a smooth surface without a grinding mark.

The first side surface 5A and the second side surface 5B extend in the a-axis direction of the SiC monocrystal and are opposed in an m-axis direction ([1-100] direction) of the SiC monocrystal. That is, the first side surface 5A and the second side surface 5B are formed by m-planes ((1-100) planes) of the SiC monocrystal. The third side surface 5C and the fourth side surface 5D extend in the m-axis direction of the SiC monocrystal and are opposed in the a-axis direction of the SiC monocrystal.

That is, the third side surface 5C and the fourth side surface 5D are formed by a-planes ((11-20) planes) of the SiC monocrystal. The first to fourth side surfaces 5A to 5D may each consist of a ground surface with grinding marks, or may each consist of a smooth surface without a grinding mark. The c-axis direction may be referred to as a “thickness direction,” the a-axis direction may be referred to as a “first direction,” and the m-axis direction may be referred to as a “second direction.”

The chip 2 may have a thickness of not less than 5 μm and not more than 350 μm. The thickness of the chip 2 may be set to a value belonging to any one range among not less than 5 μm and not more than 50 μm, not less than 50 μm and not more than 100 μm, not less than 100 μm and not more than 150 μm, not less than 150 μm and not more than 200 μm, not less than 200 μm and not more than 250 μm, not less than 250 μm and not more than 300 μm, and not less than 300 μm and not more than 350 μm. The thickness of the chip 2 is preferably not more than 150 μm.

The first to fourth side surfaces 5A to 5D may each have a length of not less than 0.5 mm and not more than 20 mm in plan view. The length of each of the first to fourth side surfaces 5A to 5D may be set to a value belonging to any one range among not less than 0.5 mm and not more than 5 mm, not less than 5 mm and not more than 10 mm, not less than 10 mm and not more than 15 mm, and not less than 15 mm and not more than 20 mm. The length of each of the first to fourth side surfaces 5A to 5D is preferably not less than 5 mm.

The SiC semiconductor device 1A includes a first semiconductor region 6 of an n-type that is formed in a region (surface layer portion) inside the chip 2 at the first main surface 3 side. The first semiconductor region 6 may have an n-type impurity concentration (peak value) of not less than 1.0×10¹⁵ cm⁻³ and not more than 1.0×10¹⁷ cm⁻³. The first semiconductor region 6 is formed in a layered shape extending along the first main surface 3 and is exposed from the first main surface 3 and the first to fourth side surfaces 5A to 5D.

In this embodiment, the first semiconductor region 6 consists of an SiC epitaxial layer. The first semiconductor region 6 may have a thickness of not less than 1 μm and not more than 50 μm. The thickness of the first semiconductor region 6 is preferably not less than 5 μm and not more than 30 μm. The thickness of the first semiconductor region 6 is particularly preferably not more than 25 μm.

The SiC semiconductor device 1A includes a second semiconductor region 7 of the n-type that is formed in a region (surface layer portion) inside the chip 2 at the second main surface 4 side. The second semiconductor region 7 is formed in a layered shape extending along the second main surface 4 and is exposed from the second main surface 4 and the first to fourth side surfaces 5A to 5D. The second semiconductor region 7 has an n-type impurity concentration higher than that of the first semiconductor region 6 and is electrically connected to the first semiconductor region 6.

The second semiconductor region 7 may have an n-type impurity concentration (peak value) of not less than 1.0×10¹⁸ cm⁻³ and not more than 1.0×10²¹ cm⁻³. In this embodiment, the second semiconductor region 7 consists of an SiC substrate. That is, the chip 2 has a laminated structure including the SiC substrate and the SiC epitaxial layer.

The second semiconductor region 7 may have a thickness of not less than 1 μm and not more than 350 μm. The thickness of the second semiconductor region 7 is preferably not less than 5 μm and not more than 50 μm. The semiconductor region 7 is thickness of the second particularly preferably not less than 5 μm and not more than 20 μm. The thickness of the second semiconductor region 7 is preferably not less than 10 μm. The thickness of the second semiconductor region 7 may exceed the thickness of the first semiconductor region 6. The thickness of the second semiconductor region 7 may be less than the thickness of the first semiconductor region 6.

The SiC semiconductor device 1A includes an active surface 8, an outer surface 9, and first to fourth connecting surfaces 10A to 10D that are formed in the first main surface 3. The active surface 8, the outer surface 9, and the first to fourth connecting surfaces 10A to 10D demarcate an active mesa 11 in the first main surface 3. The active surface 8 may be referred to as a “first surface portion,” the outer surface 9 may be referred to as a “second surface portion,” and the first to fourth connecting surfaces 10A to 10D may be referred to as “connecting surface portions.” The active surface 8, the outer surface 9, and the first to fourth connecting surfaces 10A to 10D (that is, the active mesa 11) may be considered as components of the chip 2 (first main surface 3).

The active surface 8 is formed at an interval inward from a peripheral edge of the first main surface 3 (first to fourth side surfaces 5A to 5D). The active surface 8 has a flat surface formed by a c-plane (Si plane). In this embodiment, the active surface 8 is formed in a quadrangle shape having four sides parallel to the first to fourth side surfaces 5A to 5D in plan view.

The outer surface 9 is positioned outside the active surface 8 and is recessed in the thickness direction of the chip 2 (toward the second main surface 4 side) from the active surface 8. Specifically, the outer surface 9 is recessed to a depth less than the thickness of the first semiconductor region 6 such as to expose the first semiconductor region 6. The outer surface 9 extends in a band shape along the active surface 8 and is formed in an annular shape (specifically, a quadrangle annular shape) surrounding the active surface 8 in plan view. The outer surface 9 has a flat surface formed by a c-plane (Si plane) and is formed substantially parallel to the active surface 8. The outer surface 9 is continuous to the first to fourth side surfaces 5A to 5D.

The first to fourth connecting surfaces 10A to 10D extend in the c-axis direction and connect the active surface 8 and the outer surface 9. The first connecting surface 10A is positioned at the first side surface 5A side, the second connecting surface 10B is positioned at the second side surface 5B side, the third connecting surface 10C is positioned at the third side surface 5C side, and the fourth connecting surface 10D is positioned at the fourth side surface 5D side.

The first connecting surface 10A and the second connecting surface 10B extend in the a-axis direction and are opposed in the m-axis direction in plan view. That is, the first side surface 5A and the second side surface 5B are formed by m-planes. The third connecting surface 10C and the fourth connecting surface 10D extend in the m-axis direction and are opposed in the a-axis direction in plan view. That is, the third side surface 5C and the fourth side surface 5D are formed by a-planes.

The first to fourth connecting surfaces 10A to 10D may extend substantially vertically between the active surface 8 and the outer surface 9 such as to demarcate the active mesa 11 of a quadrangle columnar shape. The first to fourth connecting surfaces 10A to 10D may be downwardly inclined from the active surface 8 toward the outer surface 9 such as to demarcate the active mesa 11 of a quadrangle pyramid shape instead. The SiC semiconductor device 1A thus includes the active mesa 11 that is demarcated in projecting shape in the first semiconductor region 6 at the first main surface 3. The active mesa 11 is formed only in the first semiconductor region 6 and is not formed in the second semiconductor region 7.

The SiC semiconductor device 1A includes a body region 12 of a p-type that is formed in a surface layer portion of the active surface 8. The body region 12 may have a p-type impurity concentration (peak value) of not less than 1.0×10¹⁶ cm⁻³ and not more than 1.0×10¹⁹ cm⁻³. The body region 12 is formed in a surface layer portion of the first semiconductor region 6 at an interval to the active surface 8 side from a bottom portion of the first semiconductor region 6 and opposes the second semiconductor region 7 with a portion of the first semiconductor region 6 interposed therebetween. The body region 12 is formed in a layered shape extending along the active surface 8. The body region 12 may be exposed from the first to fourth connecting surfaces 10A to 10D.

The SiC semiconductor device 1A includes a first trench structure 15 that is formed in the active surface 8. A gate potential is applied to the first trench structure 15. The first trench structure 15 may be referred to as a “trench gate wiring structure.” The first trench structure 15 penetrates through the body region 12 and reaches the first semiconductor region 6. The first trench structure 15 is formed at an interval to the active surface 8 side from the bottom portion of the first semiconductor region 6 and opposes the second semiconductor region 7 with a portion of the first semiconductor region 6 interposed therebetween. The first trench structure 15 preferably has a depth substantially equal to the depth of the outer surface 9.

The first trench structure 15 is formed in a peripheral edge portion of the active surface 8 at an interval from a peripheral edge of the active surface 8 (first to fourth connecting surfaces 10A to 10D) and extends in a band shape such as to surround an inner portion of the active surface 8. In this embodiment, the first trench structure 15 is formed in an annular shape (specifically, a quadrangle annular shape) extending along the first to fourth connecting surfaces 10A to 10D.

The first trench structure 15 includes a pad portion 15a and a line portion 15b. The pad portion 15a is arranged at a peripheral edge portion of the active surface 8 at an interval from a central portion of the third connecting surface 10C and is formed in a quadrangle shape in plan view. The line portion 15b is drawn out in a band shape from the pad portion 15a and extends along the peripheral edge of the active surface 8 such as to surround the inner portion of the active surface 8. The line portion 15b is formed to be narrower in width than the pad portion 15a.

The first trench structure 15 includes a first trench 16, a first insulating film 17, and a first embedded electrode 18. The first trench 16 may be referred to as a “wiring trench,” the first insulating film 17 may be referred to as a “wiring insulating film,” and the first embedded electrode 18 may be referred to as a “wiring embedded electrode.” The first trench 16 is formed in the active surface 8 and demarcates a wall surface of the first trench structure 15.

The first insulating film 17 covers a wall surface of the first trench 16 as a film. The first insulating film 17 may include at least one among a silicon oxide film, a silicon nitride film, and a silicon oxynitride film. In this embodiment, the first insulating film 17 has a single layer structure consisting of the silicon oxide film. The first insulating film 17 particularly preferably includes the silicon oxide film that consists of an oxide of the chip 2.

The first embedded electrode 18 is embedded in the first trench 16 with the first insulating film 17 interposed therebetween. The first embedded electrode 18 may project further upward than the first main surface 3. The first embedded electrode 18 may have a portion that is drawn out onto the first main surface 3 from the first trench 16. The first embedded electrode 18 may contain a conductive polysilicon.

The SiC semiconductor device 1A includes a plurality of second trench structures 20 that are formed in the active surface 8. A source potential is applied to the plurality of second trench structures 20. The second trench structures 20 may be referred to as “trench source structures.” The plurality of second trench structures 20 are formed in the inner portion of the active surface 8 at intervals from the first trench structure 15. The plurality of second trench structures 20 penetrate through the body region 12 and reach the first semiconductor region 6.

The plurality of second trench structures 20 are formed at an interval to the active surface 8 side from the bottom portion of the first semiconductor region 6 and oppose the second semiconductor region 7 with portions of the first semiconductor region 6 interposed therebetween. The plurality of second trench structures 20 preferably have a depth substantially equal to the depth of the first trench structure 15. The plurality of second trench structures 20 preferably have a depth substantially equal to the depth of the outer surface 9. The second trench structures 20 are each preferably formed to be narrower in width than the first trench structure 15.

The plurality of second trench structures 20 are arrayed at intervals in the a-axis direction and the m-axis direction in plan view. The plurality of second trench structures 20 may be arrayed in a matrix pattern in plan view. In this case, the SiC semiconductor device 1A includes the plurality of second trench structures 20 that are arrayed at intervals such as to oppose each other in the a-axis direction and the m-axis direction.

The plurality of second trench structures 20 may be arrayed in a staggered manner in plan view. In this case, the SiC semiconductor device 1A may include a plurality of groups that are arrayed at intervals in the m-axis direction and each include a plurality of second trench structures 20 that are arrayed at intervals in a single column in the a-axis direction. In this case, the plurality of second trench structures 20 belonging to one group are shifted in the a-axis direction such as to oppose regions (for example, intermediate regions) between the plurality of second trench structures 20 belonging to another group in the m-axis direction.

As a matter of course, the SiC semiconductor device 1A may include a plurality of groups that are arrayed at intervals in the a-axis direction and each include a plurality of second trench structures 20 that are arrayed at intervals in a single column in the m-axis direction. In this case, the plurality of second trench structures 20 belonging to one group are shifted in the m-axis direction such as to oppose regions (for example, intermediate regions) between the plurality of second trench structures 20 belonging to another group in the a-axis direction.

Hereinafter, the arrangement of a single second trench structure 20 shall be described. With reference to FIG. 8 to FIG. 15, the second trench structure 20 is formed in an annular shape (specifically, a quadrangle annular shape) extending in the a-axis direction and the m-axis direction in plan view in this embodiment. The second trench structure 20 includes an inner side wall 21, an outer side wall 22, and a bottom wall 23.

The inner side wall 21 forms an inner edge of the second trench structure 20 and is formed in a quadrangle shape extending in the a-axis direction and the m-axis direction in plan view. Specifically, the inner side wall 21 includes a pair of first inner side walls 21A and a pair of second inner side walls 21B.

The pair of first inner side walls 21A extend in the a-axis direction and are opposed in the m-axis direction. That is, the pair of first inner side walls 21A are demarcated by m-planes. The pair of second inner side walls 21B extend in the m-axis direction such as to be connected to the pair of first inner side walls 21A and are opposed in the a-axis direction. That is, the pair of second inner side walls 21B are demarcated by a-planes. The inner side wall 21 demarcates a first mesa portion 24 of a quadrangle shape in the active surface 8.

The outer side wall 22 forms an outer edge of the second trench structure 20 and surrounds the inner side wall 21 in plan view. The outer side wall 22 is formed in a quadrangle shape extending in the a-axis direction and the m-axis direction. Specifically, the outer side wall 22 includes a pair of first outer side walls 22A and a pair of second outer side walls 22B.

The pair of first outer side walls 22A extend in the a-axis direction and are opposed in the m-axis direction. That is, the pair of first outer side walls 22A are demarcated by m-planes. The pair of second outer side walls 22B extend in the m-axis direction such as to be connected to the pair of first outer side walls 22A and are opposed in the a-axis direction. That is, the pair of second outer side walls 22B are demarcated by a-planes.

The bottom wall 23 connects the inner side wall 21 and the outer side wall 22 and is formed in an annular shape (specifically, a quadrangle annular shape) extending in the a-axis direction and the m-axis direction in plan view. Specifically, the bottom wall 23 includes a pair of first bottom walls 23A and a pair of second bottom walls 23B.

The pair of first bottom walls 23A extend in band shapes in the a-axis direction. The pair of second bottom walls 23B extend in band shapes in the m-axis direction such as to be connected to the pair of first bottom walls 23A. The bottom wall 23 is formed by a c-plane. If the active surface 8 (first main surface 3) has the off angle inclined in the predetermined off direction at the predetermined angle with respect to the c-plane, the bottom wall 23 may have the off direction and the off angle like the active surface 8 (first main surface 3).

The second trench structure 20 includes a second trench 25, a second insulating film 26, and a second embedded electrode 27. The second trench 25 may be referred to as a “source trench,” the second insulating film 26 may be referred to as a “source insulating film,” and the second embedded electrode 27 may be referred to as a “source embedded electrode.” The second trench 25 is formed in the active surface 8 and demarcates a wall surface (the inner side wall 21, the outer side wall 22, and the bottom wall 23) of the second trench structure 20.

The second insulating film 26 covers a wall surface of the second trench 25 as a film. The second insulating film 26 may include at least one among a silicon oxide film, a silicon nitride film, and a silicon oxynitride film. In this embodiment, the second insulating film 26 has a single layer structure consisting of the silicon oxide film. The second insulating film 26 particularly preferably includes the silicon oxide film that consists of the oxide of the chip 2. The second embedded electrode 27 is embedded in the second trench 25 with the second insulating film 26 interposed therebetween. The second embedded electrode 27 may contain a conductive polysilicon.

The SiC semiconductor device 1A includes a third trench structure 30 that is formed in the active surface 8 at intervals from the plurality of second trench structures 20. A gate potential is applied to the third trench structure 30. The third trench structure 30 may be referred to as a “trench gate structure.” The third trench structure 30 penetrates through the body region 12 and reaches the first semiconductor region 6.

The third trench structure 30 is formed at an interval to the active surface 8 side from the bottom portion of the first semiconductor region 6 and opposes the second semiconductor region 7 with a portion of the first semiconductor region 6 interposed therebetween. The third trench structure 30 preferably has a depth substantially equal to the depth of the first trench structure 15 (second trench structure 20). The third trench structure 30 preferably has a depth substantially equal to the depth of the outer surface 9. The third trench structure 30 is preferably formed to be narrower in width than the first trench structure 15. A width of the third trench structure 30 is preferably substantially equal to a width of the second trench structure 20.

The third trench structure 30 is formed in a lattice pattern extending in the a-axis direction and the m-axis direction in regions between the plurality of second trench structures 20 such as to surround the plurality of second trench structures 20 in plan view. In other words, the third trench structure 30 is formed in annular shapes (specifically, quadrangle annular shapes) surrounding the respective second trench structures 20 in plan view. The third trench structure 30 demarcates, with the outer side walls 22 of the plurality of second trench structures 20, a plurality of second mesa portions 31 that extend in annular shapes (specifically, quadrangle annular shapes). The third trench structure 30 is electrically and mechanically connected to the first trench structure 15 in the peripheral edge portion of the active surface 8.

Specifically, the third trench structure 30 includes a plurality of third trench structures 30A extending in the a-axis direction and a plurality of third trench structures 30B extending in the m-axis direction. The plurality of third trench structures 30A are formed at intervals in the m-axis direction from the plurality of first outer side walls 22A such as to oppose the plurality of first outer side walls 22A in the m-axis direction and extend in band shapes in the a-axis direction in regions between the plurality of first outer side walls 22A. The plurality of third trench structures 30A are electrically and mechanically connected to the first trench structure 15 in the peripheral edge portion of the active surface 8.

Each third trench structure 30A has a pair of first gate side walls 32 extending in the a-axis direction and a first gate bottom wall 33 extending in the a-axis direction. The pair of first gate side walls 32 are formed by m-planes and the first gate bottom wall 33 is formed by a c-plane. If the active surface 8 (first main surface 3) has the off angle inclined in the predetermined off direction at the predetermined angle with respect to the c-plane, the first gate bottom wall 33 may have the off direction and the off angle like the active surface 8 (first main surface 3).

The plurality of third trench structures 30B are formed at intervals in the a-axis direction from the plurality of second outer side walls 22B such as to oppose the plurality of second outer side walls 22B in the a-axis direction and extend in band shapes in the m-axis direction in regions between the plurality of second outer side walls 22B. The plurality of third trench structures 30B intersect (specifically, are orthogonal to) the plurality of third trench structures 30A in the inner portion of the active surface 8 and, together with the plurality of third trench structures 30A, form a plurality of trench intersections 34.

In this embodiment, the plurality of trench intersections 34 each form a crossroad in plan view. If the plurality of second trench structures 20 are arrayed in the staggered manner in plan view, the plurality of trench intersections 34 each form a T-junction in plan view. The plurality of third trench structures 30B are electrically and mechanically connected to the first trench structure 15 in the peripheral edge portion of the active surface 8.

Each third trench structure 30B has a pair of second gate side walls 35 extending in the m-axis direction and a second gate bottom wall 36 extending in the m-axis direction. The pair of second gate side walls 35 are formed by a-planes and the second gate bottom wall 36 is formed by a c-plane. If the active surface 8 (first main surface 3) has the off angle inclined in the predetermined off direction at the predetermined angle with respect to the c-plane, the second gate bottom wall 36 may have the off direction and the off angle like the active surface 8 (first main surface 3). The trench intersections 34 are formed by intersections of the first gate bottom walls 33 and the second gate bottom walls 36.

The third trench structure 30 includes a third trench 37, a third insulating film 38, and a third embedded electrode 39. The third trench 37 may be referred to as a “gate trench,” the third insulating film 38 may be referred to as a “gate insulating film,” and the third embedded electrode 39 may be referred to as a “gate embedded electrode.” The third trench 37 is formed in the active surface 8 and demarcates a wall surface of the third trench structure 30. The third trench 37 is in communication with the first trench 16 in the peripheral edge portion of the active surface 8.

The third insulating film 38 covers a wall surface of the third trench 37 as a film. The third insulating film 38 is connected to the first insulating film 17 in communication portions of the first trench 16 and the third trench 37. The third insulating film 38 may include at least one among a silicon oxide film, a silicon nitride film, and a silicon oxynitride film. In this embodiment, the third insulating film 38 has a single layer structure consisting of the silicon oxide film. The third insulating film 38 particularly preferably includes the silicon oxide film that consists of the oxide of the chip 2.

The third embedded electrode 39 is embedded in the third trench 37 with the third insulating film 38 interposed therebetween. The third embedded electrode 39 is electrically and mechanically connected to the first embedded electrode 18 in communication portions of the first trench 16 and the third trench 37. The third embedded electrode 39 may contain a conductive polysilicon.

The SiC semiconductor device 1A includes a plurality of source regions 40 of the n-type that are formed in regions of a surface layer portion of the body region 12 along the third trench structure 30. Specifically, the plurality of source regions 40 are formed in the surface layer portion of the body region 12 in the plurality of second mesa portions 31. Each source region 40 has a higher n-type impurity concentration than the first semiconductor region 6. The n-type impurity concentration (peak value) of the source region 40 may be not less than 1.0×10¹⁸ cm⁻³ and not more than 1.0×10²¹ cm⁻³. The plurality of source regions 40 are each formed at an interval to the active surface 8 side from a bottom portion of the body region 12 and formed in a layered shape extending along the active surface 8.

In this embodiment, each source region 40 is formed in an annular shape (specifically, a quadrangle annular shape) extending along the second mesa portion 31 such as to surround the corresponding second trench structure 20 in plan view and is connected to the second trench structure 20 and the third trench structure 30. Each source region 40 is exposed from the first outer side walls 22A and the second outer side walls 22B of the second trench structure 20 and is exposed from the first gate side walls 32 and the second gate side walls 35 of the third trench structure 30. Each source region 40, together with the first semiconductor region 6, forms a channel inside the body region 12.

With reference to FIG. 8 to FIG. 15, the SiC semiconductor device 1A includes a plurality of well regions 41 of the p-type that are each formed in a region inside the chip 2 along the corresponding second trench structure 20. In this embodiment, the plurality of well regions 41 have a higher p-type impurity concentration than the body region 12. As a matter of course, the plurality of well regions 41 may have a lower p-type impurity concentration than the body region 12 instead. The p-type impurity concentration (peak value) of the well regions 41 may be not less than 1.0×10¹⁶ cm⁻³ and not more than 1.0×10¹⁸ cm⁻³.

Hereinafter, the arrangement of a single well region 41 shall be described specifically. In this embodiment, the well region 41 includes a well bottom wall portion 42, a well inner wall portion 43, and a well outer wall portion 44. The well bottom wall portion 42 may be referred to as a “first well portion,” the well inner wall portion 43 may be referred to as a “second well portion,” and the well outer wall portion 44 may be referred to as a “third well portion.”

The well bottom wall portion 42 is formed in a region along the bottom wall 23 of the second trench structure 20. Specifically, the well bottom wall portion 42 is formed in a region along the pair of first bottom walls 23A and the pair of second bottom walls 23B. The well bottom wall portion 42 is formed in an annular shape (specifically, a quadrangle annular shape) extending along the bottom wall 23 of the second trench structure 20 in plan view and covers a whole region of the bottom wall 23 of the second trench structure 20. The well bottom wall portion 42 is formed at an interval to the active surface 8 side from the bottom portion of the first semiconductor region 6 and opposes the second semiconductor region 7 with a portion of the first semiconductor region 6 interposed therebetween.

The well inner wall portion 43 is drawn out to the inner side wall 21 side of the second trench structure 20 from the well bottom wall portion 42 and is formed in a region along the inner side wall 21. Specifically, the well inner wall portion 43 is formed in a region inside the first mesa portion 24 along the pair of first inner side walls 21A and the pair of second inner side walls 21B.

The well inner wall portion 43 is formed in an annular shape (specifically, a quadrangle annular shape) extending along the inner side wall 21 such as to surround an inner portion of the body region 12 in plan view. The well inner wall portion 43 is connected to the body region 12 in a surface layer portion of the first mesa portion 24. A thickness of the well inner wall portion 43 on a basis of the inner side wall 21 is less than a thickness of the well bottom wall portion 42 on a basis of the bottom wall 23.

The well outer wall portion 44 is drawn out to the outer side wall 22 side of the second trench structure 20 from the bottom wall 23 side of the second trench structure 20 and is formed in a region along the outer side wall 22. Specifically, the well outer wall portion 44 is formed in a region in the second mesa portion 31 along the pair of first outer side walls 22A and the pair of second outer side walls 22B.

The well outer wall portion 44 is formed in the second mesa portion 31 in an annular shape (specifically, a quadrangle annular shape) surrounding the second trench structure 20 at an interval from the third trench structure 30. The well outer wall portion 44 is connected to the body region 12 in a surface layer portion of the second mesa portion 31. A thickness of the well outer wall portion 44 on a basis of the outer side wall 22 is less than the thickness of the well bottom wall portion 42 on the basis of the bottom wall 23.

With reference to FIG. 8 to FIG. 15, the SiC semiconductor device 1A includes a plurality of contact regions 50 of the p-type that are each formed in a region inside the chip 2 along the corresponding second trench structure 20. Specifically, the plurality of contact regions 50 are each formed in a region inside the corresponding well region 41 along the corresponding second trench structure 20.

The plurality of contact regions 50 have a higher p-type impurity concentration than the body region 12. The plurality of contact regions 50 have a higher p-type impurity concentration than the well regions 41. The p-type impurity concentration (peak value) of the contact regions 50 may be not less than 1.0×10¹⁷ cm⁻³ and not more than 1.0×10²¹ cm⁻³. The contact regions 50 preferably contain aluminum (Al) as the p-type impurity.

Hereinafter, the arrangement of a single contact region 50 shall be described specifically. The contact region 50 is formed inside the well region 41 at intervals in the m-axis direction from the pair of first outer side walls 22A of the second trench structure 20. In this embodiment, the contact region 50 includes a first contact region 51, a second contact region 52, and a third contact region 53. The first to third contact regions 51 to 53 are formed in mutually different positional relationships (relative positions) with respect to a single second trench structure 20 inside a cell region surrounded by the third trench structure 30.

The first contact region 51 is formed inside the well region 41 at intervals in the m-axis direction from the pair of first outer side walls 22A of the second trench structure 20 and is not formed in a region along the pair of first outer side walls 22A. The first contact region 51 is formed inside the well region 41 at intervals in the m-axis direction from the pair of first inner side walls 21A of the second trench structure 20 and is not formed in a region along the pair of first inner side walls 21A.

The first contact region 51 is formed in a region inside the well region 41 along one of the second bottom walls 23B of the second trench structure 20 at intervals in the m-axis direction from the pair of first bottom walls 23A and is not formed in a region along the pair of first bottom walls 23A. The first contact region 51 is preferably formed in a region along a width direction intermediate portion of the one second bottom wall 23B in plan view.

In this embodiment, the first contact region 51 includes a first bottom wall portion 54, a first inner wall portion 55, and a first outer wall portion 56. The first bottom wall portion 54 may be referred to as a “first contact portion,” the first inner wall portion 55 may be referred to as a “second contact portion,” and the first outer wall portion 56 may be referred to as a “third contact portion.”

The first bottom wall portion 54 is formed in a region inside the well region 41 (well bottom wall portion 42) along the one second bottom wall 23B at intervals from the pair of first bottom walls 23A. The first bottom wall portion 54 is preferably formed in a region along a central portion of the second bottom wall 23B. The first bottom wall portion 54 is formed at an interval to the first bottom wall 23A side from a bottom portion of the well region 41 and opposes the first semiconductor region 6 with a portion of the well region 41 interposed therebetween.

The first inner wall portion 55 is drawn out along the a-axis direction from the first bottom wall portion 54 to one second inner side wall 21B side of the second trench structure 20 and is formed in a region along the one second inner side wall 21B inside the well region 41 (well inner wall portion 43). The first inner wall portion 55 is formed in a region along an inner portion of the second inner side wall 21B at intervals in the m-axis direction from the pair of first inner side walls 21A. The first inner wall portion 55 is preferably formed in a region along a central portion of the second inner side wall 21B. The first inner wall portion 55 is drawn out from inside the well region 41 into the body region 12 in the first mesa portion 24.

The first inner wall portion 55 has a first exposed portion 57 exposed from the active surface 8 in the first mesa portion 24. The first exposed portion 57 extends in a layered shape along the active surface 8 at an interval to the active surface 8 side from the bottom portion of the body region 12 and opposes the first semiconductor region 6 with a portion of the body region 12 interposed therebetween. A thickness of the first inner wall portion 55 on a basis of the second inner side wall 21B is less than a thickness of the first bottom wall portion 54 on a basis of the second bottom wall 23B.

The first outer wall portion 56 is drawn out along the a-axis direction from the first bottom wall portion 54 to one second outer side wall 22B side of the second trench structure 20 and is formed in a region along the one second outer side wall 22B inside the well region 41 (well outer wall portion 44). The first outer wall portion 56 is formed in a region along an inner portion of the second outer side wall 22B at intervals in the m-axis direction from the pair of first outer side walls 22A. The first outer wall portion 56 is preferably formed in a region along a central portion of the second outer side wall 22B. The first outer wall portion 56 is drawn out from inside the well region 41 into the body region 12 in the second mesa portion 31.

The first outer wall portion 56 has a second exposed portion 58 exposed from the active surface 8 in the second mesa portion 31. The second exposed portion 58 extends in a layered shape along the active surface 8 at an interval to the active surface 8 side from the bottom portion of the body region 12 and opposes the first semiconductor region 6 with a portion of the body region 12 interposed therebetween. The second exposed portion 58 is formed at an interval to the second trench structure 20 side from the third trench structure 30 and is connected to the source region 40. A thickness of the first outer wall portion 56 on a basis of the second outer side wall 22B is less than the thickness of the first bottom wall portion 54 on the basis of the second bottom wall 23B.

The second contact region 52 is formed in a region inside the well region 41 different from the first contact region 51 and at intervals in the m-axis direction from the pair of first outer side walls 22A of the second trench structure 20 and is not formed in a region along the pair of first outer side walls 22A. The second contact region 52 is formed inside the well region 41 at intervals in the m-axis direction from the pair of first inner side walls 21A of the second trench structure 20 and is not formed in a region along the pair of first inner side walls 21A.

The second contact region 52 is formed in a region inside the well region 41 along the other second bottom wall 23B of the second trench structure 20 at intervals in the m-axis direction from the pair of first bottom walls 23A of the second trench structure 20 and is not formed in a region along the pair of first bottom walls 23A. The second contact region 52 is preferably formed in a region opposing the first contact region 51 in the a-axis direction in plan view. The second contact region 52 is preferably formed in a region along a width direction intermediate portion of the other second bottom wall 23B in plan view.

In this embodiment, the second contact region 52 includes a second bottom wall portion 59, a second inner wall portion 60, and a second outer wall portion 61. The second bottom wall portion 59 may be referred to as a “first contact portion,” the second inner wall portion 60 may be referred to as a “second contact portion,” and the second outer wall portion 61 may be referred to as a “third contact portion.”

The second bottom wall portion 59 is formed in a region inside the well region 41 (well bottom wall portion 42) along the other second bottom wall 23B at intervals from the pair of first bottom walls 23A. The second bottom wall portion 59 is preferably formed in a region along a central portion of the second bottom wall 23B. The second bottom wall portion 59 opposes the first semiconductor region 6 with a portion of the well region 41 interposed therebetween.

The second inner wall portion 60 is drawn out along the a-axis direction from the second bottom wall portion 59 to the other second inner side wall 21B side of the second trench structure 20 and is formed in a region along the other second inner side wall 21B inside the well region 41 (well inner wall portion 43). The second inner wall portion 60 is formed in a region along an inner portion of the second inner side wall 21B at intervals in the m-axis direction from the pair of first inner side walls 21A. The second inner wall portion 60 is preferably formed in a region along a central portion of the second inner side wall 21B. The second inner wall portion 60 is drawn out from inside the well region 41 into the body region 12 in the first mesa portion 24.

The second inner wall portion 60 has a third exposed portion 62 exposed from the active surface 8 in the first mesa portion 24. The third exposed portion 62 extends in a layered shape along the active surface 8 at an interval to the active surface 8 side from the bottom portion of the body region 12 and opposes the first semiconductor region 6 with a portion of the body region 12 interposed therebetween. A thickness of the second inner wall portion 60 on a basis of the second inner side wall 21B is less than the thickness of the second bottom wall portion 59 on the basis of the second bottom wall 23B.

The second outer wall portion 61 is drawn out along the a-axis direction from the second bottom wall portion 59 to the other second outer side wall 22B side of the second trench structure 20 and is formed in a region along the other second outer side wall 22B inside the well region 41 (well outer wall portion 44). The second outer wall portion 61 is formed in a region along an inner portion of the second outer side wall 22B at intervals in the m-axis direction from the pair of first outer side walls 22A. The second outer wall portion 61 is preferably formed in a region along a central portion of the second outer side wall 22B. The second outer wall portion 61 is drawn out from inside the well region 41 into the body region 12 in the second mesa portion 31.

The second outer wall portion 61 has a fourth exposed portion 63 exposed from the active surface 8 in the second mesa portion 31. The fourth exposed portion 63 extends in a layered shape along the active surface 8 at an interval to the active surface 8 side from the bottom portion of the body region 12 and opposes the first semiconductor region 6 with a portion of the body region 12 interposed therebetween. The fourth exposed portion 63 is formed at an interval to the second trench structure 20 side from the third trench structure 30 and is connected to the source region 40. A thickness of the second outer wall portion 61 on a basis of the second outer side wall 22B is less than the thickness of the second bottom wall portion 59 on the basis of the second bottom wall 23B.

The third contact region 53 is formed in the surface layer portion of the body region 12 in the first mesa portion 24. The third contact region 53 extends in a layered shape along the active surface 8 at an interval to the active surface 8 side from the bottom portion of the body region 12 and opposes the first semiconductor region 6 with a portion of the body region 12 interposed therebetween. The third contact region 53 is preferably formed inside the body region 12 at intervals in the m-axis direction from the pair of first inner side walls 21A of the second trench structure 20.

That is, the third contact region 53 is preferably not formed in a region along the pair of first inner side walls 21A. The third contact region 53 is formed in a band shape extending in the a-axis direction in the first mesa portion 24 and is connected to the first exposed portion 57 of the first contact region 51 and the third exposed portion 62 of the second contact region 52.

That is, in this embodiment, the contact region 50 integrally includes the first to third contact regions 51 to 53 and is formed in a band shape extending in the a-axis direction in plan view. In this embodiment, the contact region 50 has a first width W1 in the a-axis direction and has a second width W2, less than the first width W1, in the m-axis direction.

The first width W1 is greater than the width of the second trench structure 20. The width of the second trench structure 20 is a width in a direction orthogonal to a direction in which the second trench structure 20 extends. The first width W1 is greater than a width of the first inner side wall 21A of the second trench structure 20. The first width W1 is greater than a width of each first outer side wall 22A of the second trench structure 20.

The second width W2 is less than a width of each second outer side wall 22B of the second trench structure 20. The second width W2 is less than a width of the second inner side wall 21B of the second trench structure 20. The second width W2 is preferably less than the width of the second trench structure 20. As a matter of course, the second width W2 may be greater than the width of the second trench structure 20.

With reference to FIG. 8 to FIG. 15, the SiC semiconductor device 1A includes a plurality of gate well regions 65 of the p-type that are formed in regions inside the chip 2 along the plurality of trench intersections 34. The plurality of gate well regions 65 have a lower p-type impurity concentration than the contact regions 50. In this embodiment, the plurality of gate well regions 65 have a higher p-type impurity concentration than the body region 12. As a matter of course, the plurality of gate well regions 65 may have a lower p-type impurity concentration than the body region 12.

The plurality of gate well regions 65 preferably have a p-type impurity concentration substantially equal to the well regions 41. The p-type impurity concentration (peak value) of the gate well regions 65 may be not less than 1.0×10¹⁶ cm⁻³ and not more than 1.0×10¹⁸ cm⁻³. The plurality of gate well regions 65 are formed in the regions along the plurality of trench intersections 34 at intervals in the a-axis direction and the m-axis direction and expose regions of a bottom wall (the first gate bottom walls 33 and the second gate bottom walls 36) of the third trench structure 30 outside the plurality of trench intersections 34.

Each gate well region 65 covers the first gate side walls 32 of the third trench structure 30A and the second gate side walls 35 of the third trench structure 30B at corner portions of the corresponding second mesa portions 31 and is connected to the body region 12 in surface layer portions of the corresponding second mesa portions 31. The plurality of gate well regions 65 are formed at an interval to the active surface 8 side from the bottom portion of the first semiconductor region 6 and oppose the second semiconductor region 7 with portions of the first semiconductor region 6 interposed therebetween. Bottom portions of the plurality of gate well regions 65 are preferably formed at substantially the same depth position as the bottom portions of the well regions 41.

With reference to FIG. 6 and FIG. 7, the SiC semiconductor device 1A includes a wiring well region 66 that is formed in a region inside the chip 2 along the wall surface of the first trench structure 15. The wiring well region 66 has a lower p-type impurity concentration than the contact regions 50. In this embodiment, the wiring well region 66 has a higher p-type impurity concentration than the body region 12.

As a matter of course, the wiring well region 66 may have a lower p-type impurity concentration than the body region 12. The wiring well region 66 preferably has a p-type impurity concentration substantially equal to the well regions 41. The p-type impurity concentration (peak value) of the wiring well region 66 may be not less than 1.0×10¹⁶ cm⁻³ and not more than 1.0×10¹⁸ cm⁻³.

The wiring well region 66 is formed in a region along an inner wall, an outer wall, and a bottom wall of the first trench structure 15 at the pad portion 15a and the line portion 15b of the first trench structure 15 and is connected to the body region 12 in the surface layer portion of the active surface 8. The wiring well region 66 is formed at an interval to the active surface 8 side from the bottom portion of the first semiconductor region 6 and opposes the second semiconductor region 7 with a portion of the first semiconductor region 6 interposed therebetween. A bottom portion of the wiring well region 66 is preferably formed at substantially the same depth position as the bottom portions of the well regions 41.

With reference to FIG. 16, the SiC semiconductor device 1A includes an outer well region 67 of the p-type that is formed in a surface layer portion of the outer surface 9. The outer well region 67 has a lower p-type impurity concentration than the contact regions 50. In this embodiment, the outer well region 67 has a higher p-type impurity concentration than the body region 12.

As a matter of course, the outer well region 67 may have a lower p-type impurity concentration than the body region 12. The outer well region 67 preferably has a p-type impurity concentration substantially equal to the well regions 41. The p-type impurity concentration (peak value) of the outer well region 67 may be not less than 1.0×10¹⁶ cm⁻³ and not more than 1.0×10¹⁸ cm⁻³.

The outer well region 67 is formed at intervals to the active surface 8 side from the peripheral edge (first to fourth side surfaces 5A to 5D) of the outer surface 9 in plan view and extends in a band shape along the active surface 8. In this embodiment, the outer well region 67 is formed in an annular shape (specifically, a quadrangle annular shape) surrounding the active surface 8 in plan view. The outer well region 67 extends from the surface layer portion of the outer surface 9 toward surface layer portions of the first to fourth connecting surfaces 10A to 10D and covers the first to fourth connecting surfaces 10A to 10D. The outer well region 67 is electrically connected to the body region 12 in the surface layer portion of the active surface 8.

The outer well region 67 is formed at an interval to the outer surface 9 side from the bottom portion of the first semiconductor region 6 and opposes the second semiconductor region 7 with a portion of the first semiconductor region 6 interposed therebetween. The outer well region 67 is positioned further to the bottom portion side of the first semiconductor region 6 than the bottom walls 23 of the plurality of second trench structures 20. A bottom portion of the outer well region 67 is positioned further to the bottom portion side of the first semiconductor region 6 than bottom portions of the contact regions 50 (the first bottom wall portions 54 and the second bottom wall portions 59). The bottom portion of the outer well region 67 is preferably formed at substantially the same depth position as the bottom portions of the well regions 41.

The SiC semiconductor device 1A includes an outer contact region 68 of the p-type that is formed in a surface layer portion of the outer well region 67. The outer contact region 68 has a higher p-type impurity concentration than the body region 12. The outer contact region 68 has a higher p-type impurity concentration than the outer well region 67.

The outer contact region 68 preferably has a p-type impurity concentration substantially equal to the contact regions 50. The p-type impurity concentration (peak value) of the outer contact region 68 may be not less than 1.0×10¹⁷ cm⁻³ and not more than 1.0×10²¹ cm⁻³. The outer contact region 68 preferably contains aluminum (Al) as the p-type impurity.

The outer contact region 68 is formed in the surface layer portion of the outer well region 67 at intervals from the peripheral edge (first to fourth connecting surfaces 10A to 10D) of the active surface 8 and the peripheral edge (first to fourth side surfaces 5A to 5D) of the outer surface 9 in plan view and is formed in a band shape extending along the active surface 8. In this embodiment, the outer contact region 68 is formed in an annular shape (specifically, a quadrangle annular shape) surrounding the active surface 8 in plan view.

The outer contact region 68 is formed at an interval to the outer surface 9 side from the bottom portion of the outer well region 67 and opposes the first semiconductor region 6 with a portion of the outer well region 67 interposed therebetween. The outer contact region 68 is positioned further to the bottom portion side of the first semiconductor region 6 than the bottom walls 23 of the plurality of second trench structures 20. A bottom portion of the outer contact region 68 is preferably formed at substantially the same depth position as the bottom portions of the contact regions 50 (the first bottom wall portions 54 and the second bottom wall portions 59).

The SiC semiconductor device 1A includes at least one (preferably not less than two and not more than twenty) of a field region 69 of the p-type that is formed in a region in the surface layer portion of the outer surface 9 between a peripheral edge of the outer surface 9 and the outer well region 67. In this embodiment, the siC semiconductor device 1A includes four field regions 69. The plurality of field regions 69 are formed in an electrically floating state and relax an electric field inside the chip 2 at the outer surface 9.

A number, width, depth, p-type impurity concentration, etc., of the field regions 69 are arbitrary and can take on various values in accordance with the electric field to be relaxed. The plurality of field regions 69 may have a lower p-type impurity concentration than the outer contact region 68. The plurality of field regions 69 may have a higher p-type impurity concentration than the outer well region 67. The plurality of field regions 69 may have a lower p-type impurity concentration than the outer well region 67. The p-type impurity concentration (peak value) of the field regions 69 may be not less than 1.0×10¹⁶ cm⁻³ and not more than 1.0×10²¹ cm⁻³.

The plurality of field regions 69 are arrayed at intervals to the peripheral edge side of the outer surface 9 from the outer contact region 68 side. The plurality of field regions 69 are formed in band shapes extending along the active surface 8 in plan view. In this embodiment, the plurality of field regions 69 are formed in annular shapes (specifically, quadrangle annular shapes) surrounding the active surface 8 in plan view.

The plurality of field regions 69 are formed at an interval to the outer surface 9 side from the bottom portion of the first semiconductor region 6 and oppose the second semiconductor region 7 with a portion of the first semiconductor region 6 interposed therebetween. The plurality of field regions 69 are positioned further to the bottom portion side of the first semiconductor region 6 than the bottom walls 23 of the plurality of second trench structures 20. Bottom portions of the plurality of field regions 69 are positioned further to the bottom portion side of the first semiconductor region 6 than the bottom portions of the contact regions 50 (the first bottom wall portions 54 and the second bottom wall portions 59). The bottom portions of the plurality of field regions 69 may be formed at substantially the same depth position as the bottom portions of the well regions 41.

The SiC semiconductor device 1A includes a main surface insulating film 70 that covers the first main surface 3. The main surface insulating film 70 has a laminated structure including a first main surface insulating film 71 and a second main surface insulating film 72. The first main surface insulating film 71 covers the active surface 8, the outer surface 9, and the first to fourth connecting surfaces 10A to 10D.

On the active surface 8, the first main surface insulating film 71 is continuous to the first insulating film 17 and the third insulating film 38 and exposes the first embedded electrode 18, the second embedded electrodes 27, and the third embedded electrode 39. On the outer surface 9 and the first to fourth connecting surfaces 10A to 10D, the main surface insulating film 70 covers the outer contact region 68, the outer well region 67, and the plurality of field regions 69.

The first main surface insulating film 71 may be continuous to the first to fourth side surfaces 5A to 5D. In this case, an outer wall of the first main surface insulating film 71 may consist of a ground surface with grinding marks. The outer wall of the first main surface insulating film 71 may form a single ground surface with the first to fourth side surfaces 5A to 5D. As a matter of course, the outer wall of the first main surface insulating film 71 may consist of a smooth surface without a grinding mark. Also, the outer wall of the first main surface insulating film 71 may be formed at an interval inward from the peripheral edge of the outer surface 9 and expose the first semiconductor region 6 from a peripheral edge portion of the outer surface 9.

The first main surface insulating film 71 may include at least one among a silicon oxide film, a silicon nitride film, and a silicon oxynitride film. In this embodiment, the first main surface insulating film 71 has a single layer structure consisting of the silicon oxide film. The first main surface insulating film 71 particularly preferably includes the silicon oxide film that consists of the oxide of the chip 2.

The second main surface insulating film 72 covers the active surface 8, the outer surface 9, and the first to fourth connecting surfaces 10A to 10D with the first main surface insulating film 71 interposed therebetween. On the active surface 8, the second main surface insulating film 72 covers the first trench structure 15 and the third trench structure 30. On the outer surface 9 and the first to fourth connecting surfaces 10A to 10D, the second main surface insulating film 72 covers the outer contact region 68, the outer well region 67, and the plurality of field regions 69.

In this embodiment, the second main surface insulating film 72 is continuous to the first to fourth side surfaces 5A to 5D. An outer wall of the second main surface insulating film 72 may consist of a ground surface with grinding marks. The outer wall of the second main surface insulating film 72 may form a single ground surface with the first to fourth side surfaces 5A to 5D. As a matter of course, the outer wall of the second main surface insulating film 72 may consist of a smooth surface without a grinding mark. Also, the outer wall of the second main surface insulating film 72 may be formed at an interval inward from the peripheral edge of the outer surface 9 and expose the first semiconductor region 6 from the peripheral edge portion of the outer surface 9.

The second main surface insulating film 72 may include at least one among a silicon oxide film, a silicon nitride film, and a silicon oxynitride film. In this embodiment, the second main surface insulating film 72 has a single layer structure consisting of the silicon oxide film.

The SiC semiconductor device 1A includes a side wall structure 73 that is arranged inside the main surface insulating film 70 such as to cover at least one of the first to fourth connecting surfaces 10A to 10D on the outer surface 9. Specifically, the side wall structure 73 is arranged on the first main surface insulating film 71 and is covered by the second main surface insulating film 72. In this embodiment, the side wall structure 73 is formed in an annular shape (specifically, a quadrangle annular shape) surrounding the active surface 8 in plan view. The side wall structure 73 may contain an inorganic insulator or a polysilicon.

The SiC semiconductor device 1A includes one or a plurality (in this embodiment, one) of a first gate opening 74 that is formed in the main surface insulating film 70. The first gate opening 74 exposes the pad portion 15a of the first trench structure 15. The SiC semiconductor device 1A includes one or a plurality (in this embodiment, one) of a second gate opening 75 that is formed in the main surface insulating film 70. The second gate opening 75 extends in a band shape along the line portion 15B of the first trench structure 15 and exposes the first embedded electrode 18 of the line portion 15b.

The SiC semiconductor device 1A includes a plurality of source openings 76 that are formed at intervals in the main surface insulating film 70. The plurality of source openings 76 each expose the corresponding second trench structure 20, the corresponding first mesa portion 24, and the corresponding second mesa portion 31. The plurality of source openings 76 each expose the body region 12 and the contact region 50 from the corresponding first mesa portion 24 and expose the source region 40 and the contact region 50 from the corresponding second mesa portion 31. In this embodiment, each source opening 76 is formed in a quadrangle shape in plan view.

The SiC semiconductor device 1A includes one or a plurality (in this embodiment, one) of an outer opening 77 that is formed in the main surface insulating film 70. The outer opening 77 extends in a band shape or an annular shape along the outer contact region 68 and exposes the outer contact region 68.

The SiC semiconductor device 1A includes a gate electrode 80 that is arranged on the main surface insulating film 70. The gate electrode 80 may be referred to as a “gate main surface electrode.” The gate electrode 80 includes a gate pad electrode 81 and a gate line electrode 82. The gate pad electrode 81 is arranged on the pad portion 15a of the first trench structure 15 at an interval from the peripheral edge of the active surface 8. In this embodiment, the gate pad electrode 81 is formed in a quadrangle shape in plan view. The gate pad electrode 81 enters into the first gate opening 74 from above the main surface insulating film 70 and is electrically connected to the first embedded electrode 18 of the pad portion 15a.

The gate line electrode 82 is drawn out onto the line portion 15b of the first trench structure 15 from the gate pad electrode 81. In this embodiment, the gate line electrode 82 covers the line portion 15b at an interval from the peripheral edge of the active surface 8. The gate line electrode 82 is formed in a band shape extending along the line portion 15b in plan view.

In this embodiment, the gate line electrode 82 extends along the first to third side surfaces 5A to 5C (first to third connecting surfaces 10A to 10C) and has a pair of open ends 83 at portions along the fourth side surface 5D (fourth connecting surface 10D). The gate line electrode 82 enters into the second gate opening 75 from above the main surface insulating film 70 and is electrically connected to the first embedded electrode 18 of the line portion 15b.

The gate electrode 80 may include at least one type among a Ti film, a TiN film, a W film, an Al film, a Cu film, an Al alloy film, a Cu alloy film and a conductive polysilicon film. The gate electrode 80 may include at least one of a pure Cu film (a Cu film with a purity of not less than 99%), a pure Al film (an Al film with a purity of not less than 99%), an AlCu alloy film, an AlSi alloy film and an AlSiCu alloy film. In this embodiment, the gate electrode 80 has a laminated structure that includes a Ti film, a TiN film, and an Al alloy film (in this embodiment, an AlCu alloy film) laminated in that order from the chip 2 side.

The SiC semiconductor device 1A includes a source electrode 85 arranged on the main surface insulating film 70 at an interval from the gate electrode 80. The source electrode 85 may be referred to as a “source main surface electrode.” The source electrode 85 includes a source pad electrode 86 and a source line electrode 87.

The source pad electrode 86 is arranged in a region on the main surface insulating film 70 demarcated by the gate pad electrode 81 and the gate line electrode 82 and covers the plurality of second trench structures 20 and the third trench structures 30. The source pad electrode 86 is formed in a polygonal shape that has a concave portion recessed in a concave shape along the gate pad electrode 81 in plan view.

The source pad electrode 86 covers the plurality of third trench structures 30 with the main surface insulating film 70 interposed therebetween and enters into the plurality of source openings 76 from above the main surface insulating film 70. The source pad electrode 86 is electrically connected to the second embedded electrode 27 of the corresponding second trench structure 20, the corresponding first mesa portion 24, and the corresponding second mesa portion 31 inside the corresponding source opening 76. The source pad electrode 86 is electrically connected to the body region 12 and the contact region 50 in the corresponding first mesa portion 24 and is electrically connected to the source region 40 and the contact region 50 in the corresponding second mesa portion 31.

The source line electrode 87 is drawn out in a band shape onto the outer surface 9 from the source pad electrode 86. Specifically, the source line electrode 87 passes through a region between the pair of open ends 83 of the gate line electrode 82 from the source pad electrode 86 and is drawn out onto the outer surface 9. The source line electrode 87 has, in a region between the active surface 8 and the outer surface 9, a portion opposing the side wall structure 73 with the second main surface insulating film 72 interposed therebetween.

The source line electrode 87 extends in a band shape along the outer contact region 68 in plan view. In this embodiment, the source line electrode 87 is formed in an annular shape (specifically, a quadrangle annular shape) surrounding the gate pad electrode 81, the gate line electrode 82, and the source pad electrode 86 in plan view. The source line electrode 87 enters into the outer opening 77 from above the main surface insulating film 70 and is electrically connected to the outer contact region 68.

The source electrode 85 may include at least one type among a Ti film, a TiN film, a W film, an Al film, a Cu film, an Al alloy film, a Cu alloy film and a conductive polysilicon film. The source electrode 85 may include at least one of a pure Cu film (a Cu film with a purity of not less than 99%), a pure Al film (an Al film with a purity of not less than 99%), an AlCu alloy film, an AlSi alloy film and an AlSiCu alloy film. In this embodiment, the source electrode 85 has a laminated structure that includes a Ti film and an Al alloy film (in this embodiment, an AlSiCu alloy film) laminated in that order from the chip 2 side. That is, the source electrode 85 contains the same conductive materials as the gate electrode 80.

The SiC semiconductor device 1A includes a drain electrode 88 that covers the second main surface 4. The drain electrode 88 is electrically connected to the second main surface 4. The drain electrode 88 forms an ohmic contact with the second semiconductor region 7 that is exposed from the second main surface 4. The drain electrode 88 may cover a whole region of the second main surface 4 such as to be continuous with the peripheral edge of the chip 2 (first to fourth side surfaces 5A to 5D). A breakdown voltage that can be applied between the source electrode 85 and the drain electrode 88 may be not less than 500 V and not more than 3000 V.

As described above, the SiC semiconductor device 1A includes the chip 2, the second trench structures 20 (trench structures), and the contact regions 50 of the p-type. The chip 2 includes the SiC monocrystal and has the first main surface 3. Each second trench structure 20 has the first outer side walls 22A (first side walls) and the second outer side walls 22B (second side walls) and is formed in the first main surface 3.

The first outer side walls 22A extend in the a-axis direction of the SiC monocrystal. The second outer side walls 22B extend in the m-axis direction of the SiC monocrystal. That is, the first outer side walls 22A are formed by m-planes of the SiC monocrystal and the second outer side walls 22B are formed by a-planes of the SiC monocrystal. Each contact region 50 is formed in a region inside the chip 2 along the corresponding second trench structure 20 at intervals in the m-axis direction from the first outer side walls 22A.

When a contact region 50 that is arranged along a first outer side wall 22A is formed inside the chip 2, a crystal defect (so-called m-plane defect) along an m-plane of the SiC monocrystal is at times generated with the contact region 50 as a starting point in a region along the first outer side wall 22A due to modification of the SiC monocrystal in accompaniment with introduction of the contact region 50. Electrical characteristics of an SiC semiconductor device are degraded by this type of crystal defect.

On the other hand, with the SiC semiconductor device 1A, each contact region 50 is formed at intervals in the m-axis direction from the corresponding first outer side walls 22A inside the chip 2. The m-plane defect (crystal defect) with the contact region 50 as the starting point can thus be suppressed in a region inside the chip 2 along the first outer side walls 22A.

The SiC semiconductor device 1A that can be improved in electrical characteristics can thereby be provided. For example, by suppressing the m-plane defect with the contact region 50 as the starting point, a leak current due to the m-plane defect can be suppressed. For example, suppression of the m-plane defect is effective in terms of suppressing a zero gate voltage drain current IDSS due to the m-plane defect. The zero gate voltage drain current IDSS is a leak current that flows between a drain and a source in a state where a gate and the source are short circuited.

Each second trench structure 20 has the bottom wall 23 that connects the first outer side walls 22A and the second outer side walls 22B and the contact region 50 is preferably formed in a region inside the chip 2 along at least one among the bottom wall 23 and the second outer side walls 22B. In this case, by the contact region 50 arranged along both the bottom wall 23 and the second outer side walls 22B, a formation region of the contact region 50 can be increased while suppressing the m-plane defect. A resistance value due to the contact region 50 can thereby be reduced and therefore, the electrical characteristics can be improved.

The contact region 50 is preferably formed in a band shape extending in the a-axis direction. Even according to such a structure, the formation region of the contact region 50 can be increased while suppressing the m-plane defect. The contact region 50 preferably has the first width W1 in the a-axis direction and the second width W2, less than the first width W1, in the m-axis direction.

According to this structure, distances between the first outer side walls 22A and the contact region 50 can be increased. The m-plane defect in a region inside the chip 2 along the first outer side walls 22A can thereby be suppressed while suppressing an influence of alignment deviation. In this case, the second width W2 is preferably less than the width of the second outer side walls 22B of the second trench structure 20. Also, the first width W1 may be not less than the width of the first outer side walls 22A of the second trench structure 20.

The SiC semiconductor device 1A preferably includes the well regions 41 of the p-type that are formed in regions inside the chip 2 along the first outer side walls 22A. In this case, each contact region 50 preferably has a higher p-type impurity concentration than each well region 41. According to this structure, a breakdown voltage can be improved by making use of a depletion layer spreading with the well region 41 as a starting point while suppressing the m-plane defect with the contact region 50 as the starting point.

Each well region 41 is preferably formed in a region inside the chip 2 along the corresponding second trench structure 20. In this case, the contact region 50 is preferably formed inside the well region 41. The well region 41 is preferably formed in a region inside the chip 2 along at least one among the bottom wall 23 and the second outer side walls 22B. With the well region 41 arranged along both the bottom wall 23 and the second outer side walls 22B, the breakdown voltage can be improved appropriately.

The SiC semiconductor device 1A preferably includes the body region 12 of the p-type that is formed in a surface layer portion of the first main surface 3. In this case, the second trench structures 20 are preferably formed in the first main surface 3 such as to penetrate through the body region 12. Also, the contact regions 50 preferably have a higher impurity concentration than the body region 12.

Each second trench structure 20 may be formed in an annular shape in plan view. The second trench structure 20 preferably has the first bottom walls 23A that extend in band shapes in the a-axis direction and the second bottom walls 23B that extend in band shapes in the m-axis direction. In this case, the contact region 50 is preferably formed in a region along the second bottom walls 23B at intervals in the m-axis direction from the first bottom walls 23A. According to this structure, the m-plane defect with the contact region 50 as the starting point can be suppressed in a region inside the chip 2 along the first bottom walls 23A.

The SiC semiconductor device 1A may include the first mesa portions 24 demarcated in the first main surface 3 by the second trench structures 20. In this case, each contact region 50 preferably has a portion positioned in the surface layer portion of the first main surface 3 in the corresponding first mesa portion 24. According to this structure, the formation region of the contact region 50 can be expanded using the first mesa portion 24 while suppressing the m-plane defect in a region along the first outer side walls 22A.

The SiC semiconductor device 1A preferably includes the third trench structure 30 that is formed in the first main surface 3 at intervals from the second trench structures 20. In this case, the SiC semiconductor device 1A preferably includes the source regions 40 of the n-type that are formed in regions along the third trench structure 30 in the surface layer portion of the first main surface 3.

The third trench structure 30 may be formed in the first main surface 3 at intervals in the m-axis direction from the first outer side walls 22A of the second trench structures 20 such as to extend in the a-axis direction. According to this structure, the m-plane defect with the contact region 50 as the starting point can be suppressed in regions between the second trench structures 20 and the third trench structure 30. The third trench structure 30 may be formed in the first main surface 3 at intervals in the a-axis direction from the second outer side walls 22B of the second trench structures 20 such as to extend in the m-axis direction. The third trench structure 30 may be formed in an annular shape surrounding the second trench structures 20 in plan view.

In another aspect, the SiC semiconductor device 1A may include the chip 2, the first semiconductor region 6 of the n-type, the body region 12 of the p-type, the second trench structures 20 as the trench source structures, the third trench structure 30 as the trench gate structure, the source regions 40 of the n-type, and the contact regions 50 of the p-type. The chip 2 includes the SiC monocrystal and has the first main surface 3. The first semiconductor region 6 is formed in the surface layer portion of the first main surface 3. The body region 12 is formed in the surface layer portion of the first semiconductor region 6.

Each second trench structure 20 has the first outer side walls 22A (first side walls) and the second outer side walls 22B (second side walls) and is formed in the first main surface 3. The first outer side walls 22A extend in the a-axis direction of the SiC monocrystal. The second outer side walls 22B extend in the m-axis direction of the SiC monocrystal. That is, the first outer side walls 22A are formed by m-planes of the SiC monocrystal and the second outer side walls 22B are formed by a-planes of the SiC monocrystal.

The third trench structure 30 is formed in the first main surface 3 at intervals in the m-axis direction from the first outer side walls 22A of the second trench structures 20 such as to penetrate through the body region 12. The source regions 40 are formed in the regions of the surface layer portion of the body region 12 along the third trench structure 30. The contact regions 50 are formed in regions inside the chip 2 along the second trench structures 20 at intervals in the m-axis direction from the first outer side walls 22A of the second trench structures 20.

According to this structure, the m-plane defect (crystal defect) with the contact region 50 as the starting point can be suppressed in regions between the second trench structures 20 and the third trench structure 30. The SiC semiconductor device 1A that can be improved in the electrical characteristics can thereby be provided. For example, by suppressing the m-plane defect with the contact region 50 as the starting point, the leak current due to the m-plane defect can be suppressed. For example, suppression of the m-plane defect is effective in terms of suppressing the zero gate voltage drain current IDSS due to the m-plane defect.

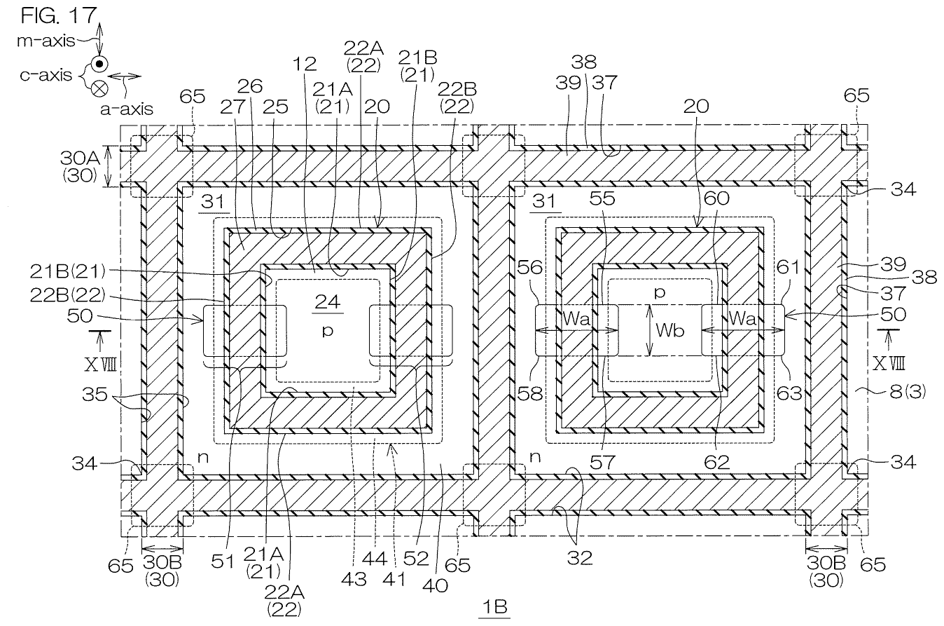

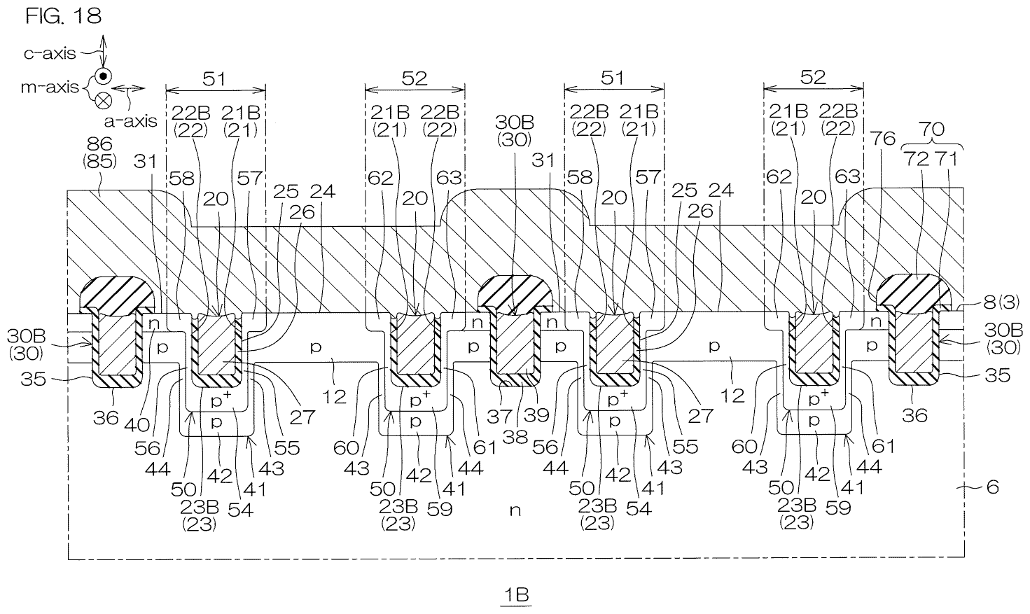

FIG. 17 is a plan view corresponding to FIG. 8 and showing an SiC semiconductor device 1B according to a second embodiment. FIG. 18 is a cross sectional view taken along line XVIII-XVIII shown in FIG. 17. The SiC semiconductor device 1B is a device that exhibits the same effects as the SiC semiconductor device 1A. The SiC semiconductor device 1A described above includes the contact regions 50 each composed of the first to third contact regions 51 to 53.

On the other hand, each contact region 50 of the SiC semiconductor device 1B does not include the third contact region 53 and includes just the first contact region 51 and the second contact region 52. As a matter of course, the contact region 50 may consist of just either the first contact region 51 or the second contact region 52.

The first contact region 51 and the second contact region 52 each have a first width Wa in the a-axis direction and a second width Wb in the m-axis direction. The first width Wa is less than the width of the first outer side walls 22A of the second trench structure 20. The first width Wa is less than the width of the first inner side walls 21A of the second trench structure 20. The first width Wa is greater than the width of the second trench structure 20.

The second width Wb is less than the width of the second outer side walls 22B of the second trench structure 20. The second width Wb is less than the width of the second inner side walls 21B of the second trench structure 20. The second width Wb is less than the first width Wa. The second width Wb is preferably less than the width of the second trench structure 20. As a matter of course, the second width Wb may be greater than the width of the second trench structure 20. Also, if the second width Wb is less than the width of the second inner side walls 21B, it may be greater than the first width Wa.

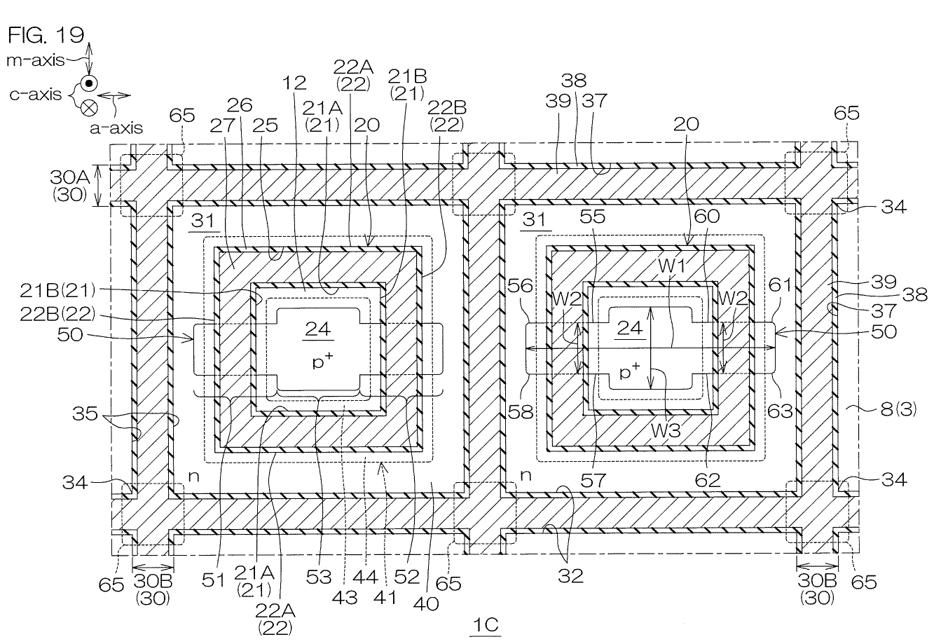

FIG. 19 is a plan view corresponding to FIG. 8 and showing an SiC semiconductor device 1C according to a third embodiment. The SiC semiconductor device 1C is a device that exhibits the same effects as the SiC semiconductor device 1A. The SiC semiconductor device 1A described above includes the contact regions 50 each composed of the first to third contact regions 51 to 53 having the uniform second width W2 in the m-axis direction.

On the other hand, each contact region 50 of the SiC semiconductor device 1C is composed of the first contact region 51 having the second width W2 in the m-axis direction, the second contact region 52 having the second width W2 in the m-axis direction, and the third contact region 53 having a third width W3, differing from the second width W2, in the m-axis direction. Specifically, the third width W3 is greater than the second width W2 and is not more than the width of the second inner side walls 21B. The third width W3 is preferably less than the width of the second inner side walls 21B.

The third contact region 53 may be formed at intervals from the pair of second inner side walls 21B such as to contact the pair of first inner side walls 21A. The third contact region 53 may be formed at intervals from the pair of first inner side walls 21A such as to contact the pair of second inner side walls 21B. The third contact region 53 may be formed in a whole region of the surface layer portion of the body region 12 inside the first mesa portion 24. In this case, the third contact region 53 may contact the pair of first inner side walls 21A and the pair of second inner side walls 21B of the second trench structure 20.

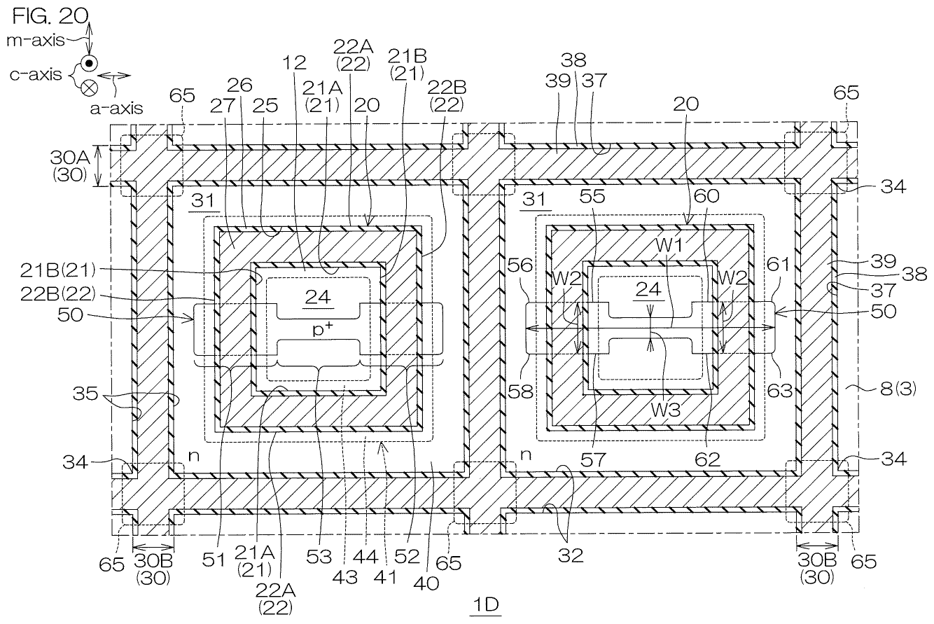

FIG. 20 is a plan view corresponding to FIG. 8 and showing an SiC semiconductor device 1D according to a fourth embodiment. The SiC semiconductor device 1D is a device that exhibits the same effects as the Sic semiconductor device 1A. The SiC semiconductor device 1A described above includes the contact regions 50 each composed of the first to third contact regions 51 to 53 having the uniform second width W2 in the m-axis direction.

On the other hand, each contact region 50 of the SiC semiconductor device 1D is composed of the first contact region 51 having the second width W2 in the m-axis direction, the second contact region 52 having the second width W2 in the m-axis direction, and the third contact region 53 having a third width W3, differing from the second width W2, in the m-axis direction. Specifically, the third width W3 is less than the second width W2.

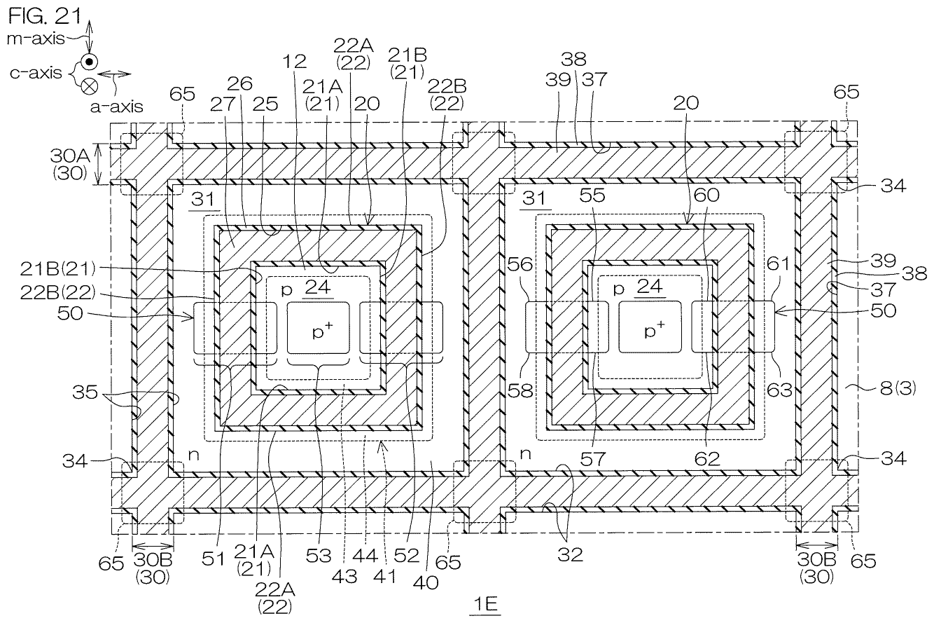

FIG. 21 is a plan view corresponding to FIG. 8 and showing an SiC semiconductor device 1E according to a fifth embodiment. The SiC semiconductor device 1E is a device that exhibits as the same effects the SiC semiconductor device 1A. The SiC semiconductor device 1A described above includes the contact regions 50 each having the third contact region 53 that is connected to the first contact region 51 and the second contact region 52. On the other hand, each contact region 50 of the SiC semiconductor device 1E has the third contact region 53 that, in the first mesa portion 24, is formed in the surface layer portion of the body region 12 at intervals from the first contact region 51 and the second contact region 52. In regard to the m-axis direction, the third contact region 53 may be formed wider in width than the first contact region 51 (second contact region 52) or narrower in width than the first contact region 51 (second contact region 52).

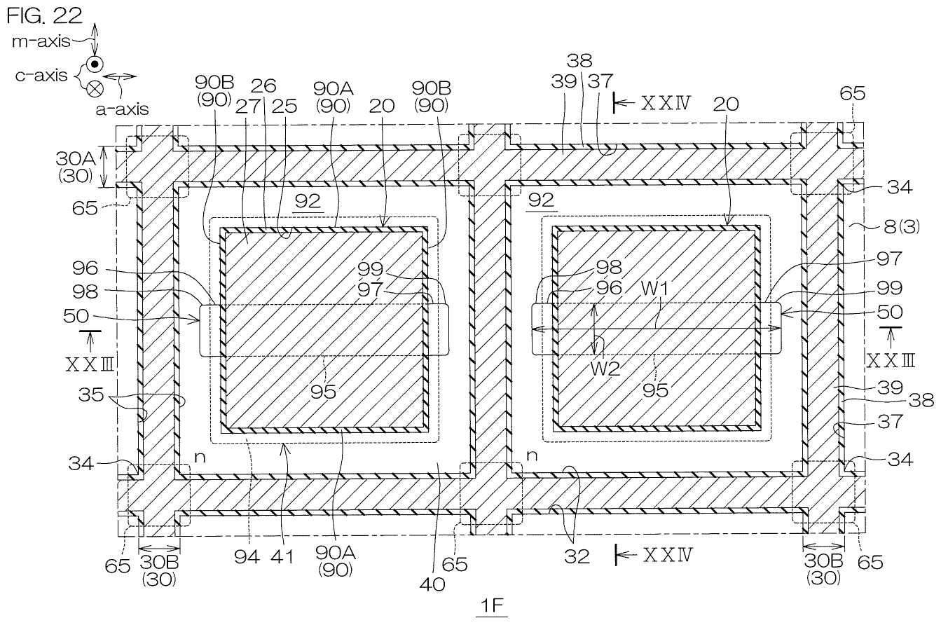

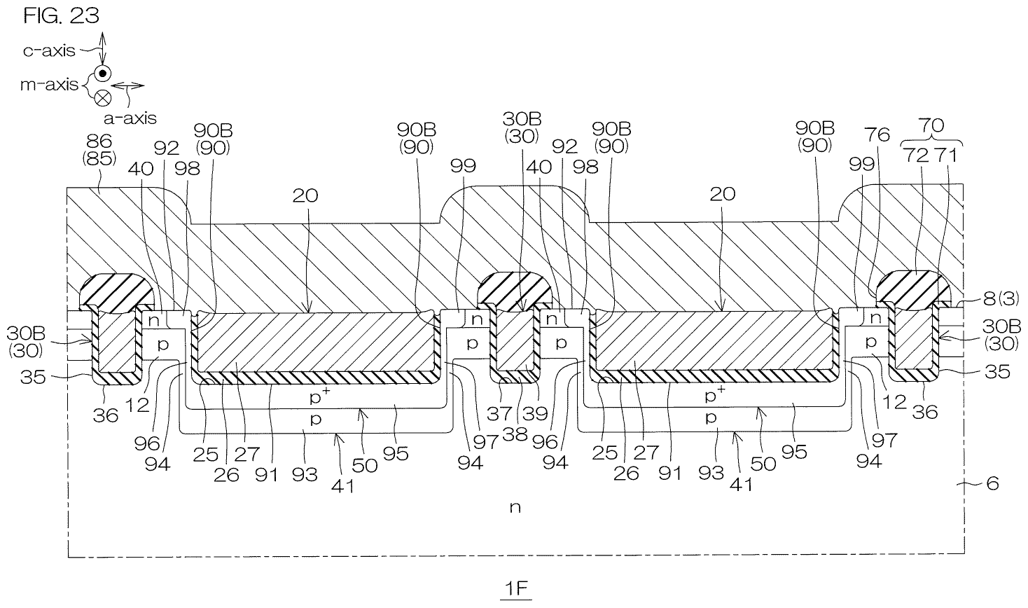

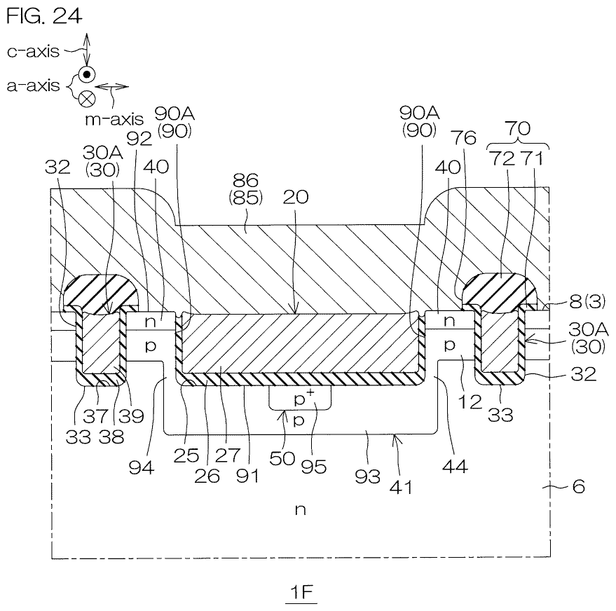

FIG. 22 is a plan view corresponding to FIG. 8 and showing an SiC semiconductor device 1F according to a sixth embodiment. FIG. 23 is a cross sectional view taken along line XXIII-XXIII shown in FIG. 22. FIG. 24 is a cross sectional view taken along line XXIV-XXIV shown in FIG. 22. The SiC semiconductor device 1F is a device that exhibits the same effects as the SiC semiconductor device 1A. The SiC semiconductor device 1A described above includes the second trench structures 20 that are each formed in the annular shape extending in the a-axis direction and the m-axis direction in plan view.

On the other hand, the SiC semiconductor device 1F includes the second trench structures 20 that are each formed in a quadrangle shape having four sides extending in the a-axis direction and the m-axis direction in plan view. As in the case of the first embodiment, each second trench structure 20 includes the second trench 25, the second insulating film 26, and the second embedded electrode 27.

In this embodiment, each second trench structure 20 includes a side wall 90 and a bottom wall 91. The side wall 90 is formed in a quadrangle shape extending in the a-axis direction and the m-axis direction in plan view. Specifically, the side wall 90 includes a pair of first side walls 90A and a pair of second side walls 90B. The pair of first side walls 90A extend in the a-axis direction and are opposed in the m-axis direction. That is, the pair of first side walls 90A are demarcated by m-planes. The pair of second side walls 90B extend in the m-axis direction such as to be connected to the pair of first side walls 90A and are opposed in the a-axis direction. That is, the pair of second side walls 90B are demarcated by a-planes.

The bottom wall 91 is formed in a quadrangle shape extending flatly along the a-axis direction and the m-axis direction in plan view and connects the pair of first side walls 90A and the pair of second side walls 90B. The bottom wall 91 is formed by a c-plane. If the active surface 8 (first main surface 3) has the off angle inclined in the predetermined off direction at the predetermined angle with respect to the c-plane, the bottom wall 91 may have the off direction and the off angle like the active surface 8 (first main surface 3).

As in the case of the first embodiment, the third trench structure 30 is formed in a lattice pattern (in annular shapes) extending in the a-axis direction and the m-axis direction in the regions between the plurality of second trench structures 20 such as to surround the plurality of second trench structures 20 in plan view. In this embodiment, the third trench structure 30 demarcates, with the side walls 90 of the plurality of second trench structures 20, a plurality of mesa portions 92 that extend in annular shapes (specifically, quadrangle annular shapes).

As in the case of the first embodiment, the third trench structure 30 includes the plurality of third trench structures 30A and the plurality of third trench structures 30B. In this embodiment, the plurality of third trench structures 30A are formed at intervals in the m-axis direction from the plurality of first side walls 90A such as to oppose the plurality of first side walls 90A in the m-axis direction and extend in band shapes in the a-axis direction in regions between the plurality of first side walls 90A. In this embodiment, the plurality of third trench structures 30B are formed at intervals in the a-axis direction from the plurality of second side walls 90B such as to oppose the plurality of second side walls 90B in the a-axis direction and extend in band shapes in the m-axis direction in regions between the plurality of second side walls 90B.

In this embodiment, each well region 41 includes a well bottom wall portion 93 and a well side wall portion 94. The well bottom wall portion 93 may be referred to as a “first well portion” and the well side wall portion 94 may be referred to as a “second well portion.” The well bottom wall portion 93 is formed in a region along the bottom wall 91 of the corresponding second trench structure 20. Specifically, the well bottom wall portion 93 covers a whole region of the bottom wall 91. The well bottom wall portion 93 is formed at an interval to the active surface 8 side from the bottom portion of the first semiconductor region 6 and opposes the second semiconductor region 7 with a portion of the first semiconductor region 6 interposed therebetween.

The well side wall portion 94 is drawn out to the side wall 90 side of the second trench structure 20 from the well bottom wall portion 93 side and is formed in a region along the side wall 90. Specifically, the well side wall portion 94 is formed in a region in the mesa portion 92 along the pair of first side walls 90A and the pair of second side walls 90B.

The well side wall portion 94 is formed in an annular shape (specifically, a quadrangle annular shape) surrounding the second trench structure 20 in the mesa portion 92 at an interval from the third trench structure 30. The well side wall portion 94 is connected to the body region 12 in a surface layer portion of the mesa portion 92. A thickness of the well side wall portion 94 on a basis of the side wall 90 is less than a thickness of the well bottom wall portion 93 on a basis of the bottom wall 91.

In this embodiment, each contact region 50 is formed in a region inside the well region 41 along the second trench structure 20 at intervals in the m-axis direction from the pair of first side walls 90A of the second trench structure 20 and is not formed in a region along the pair of first side walls 90A. The contact region 50 is preferably formed in a region along a central portion of the bottom wall 91 in plan view.

In this embodiment, the contact region 50 includes a bottom wall portion 95, a first side wall portion 96, and a second side wall portion 97. The bottom wall portion 95 may be referred to as a “first contact portion,” the first side wall portion 96 may be referred to as a “second contact portion,” and the second side wall portion 97 may be referred to as a “third contact portion.”

The bottom wall portion 95 is formed in a region inside the well region 41 (well bottom wall portion 93) along an inner portion of the bottom wall 91 at intervals in the m-axis direction from the pair of first side walls 90A. The bottom wall portion 95 is formed in a band shape extending in the a-axis direction along the bottom wall 91 in plan view. The bottom wall portion 95 preferably covers a central portion of the bottom wall 91 in plan view.

The first side wall portion 96 is drawn out along the a-axis direction from the bottom wall portion 95 to one second side wall 90B side of the second trench structure 20 and is formed in a region along the one second side wall 90B inside the well region 41 (well side wall portion 94). The first side wall portion 96 is formed in a region along an inner portion of the second side wall 90B at intervals in the m-axis direction from the pair of first side walls 90A. The first side wall portion 96 preferably covers a central portion of the second side wall 90B in plan view. The first side wall portion 96 is drawn out from inside the well region 41 into the body region 12 in the mesa portion 92.

The first side wall portion 96 has a first exposed portion 98 exposed from the active surface 8 in the mesa portion 92. The first exposed portion 98 extends in a layered shape along the active surface 8 at an interval to the active surface 8 side from the bottom portion of the body region 12 and opposes the first semiconductor region 6 with a portion of the body region 12 interposed therebetween. The first exposed portion 98 is formed at an interval to the second trench structure 20 side from the third trench structure 30 and is connected to the source region 40. A thickness of the first side wall portion 96 on a basis of the first side wall portion 96 is less than a thickness of the bottom wall portion 95 on a basis of the bottom wall 91.

The second side wall portion 97 is drawn out along the a-axis direction from the bottom wall portion 95 to the other second side wall 90B side of the second trench structure 20 and is formed in a region along the other second side wall 90B inside the well region 41 (well side wall portion 94). The second side wall portion 97 is formed in a region along an inner portion of the second side wall 90B at intervals in the m-axis direction from the pair of first side walls 90A. The second side wall portion 97 is drawn out from inside the well region 41 into the body region 12 in the mesa portion 92.

The second side wall portion 97 has a second exposed portion 99 exposed from the active surface 8 in the mesa portion 92. The second exposed portion 99 extends in a layered shape along the active surface 8 at an interval to the active surface 8 side from the bottom portion of the body region 12 and opposes the first semiconductor region 6 with a portion of the body region 12 interposed therebetween. The second exposed portion 99 is formed at an interval to the second trench structure 20 side from the third trench structure 30 and is connected to the source region 40. A thickness of the second side wall portion 97 on a basis of the first side wall portion 96 is less than the thickness of the bottom wall portion 95 on the basis of the bottom wall 91.

In this embodiment, the contact region 50 is formed in a band shape extending in the a-axis direction in plan view. In this embodiment, the contact region 50 has the first width W1 in the a-axis direction and has the second width W2, less than the first width W1, in the m-axis direction. The first width W1 is greater than the width of the second trench structure 20. The first width W1 is greater than a width of each first side wall 90A of the second trench structure 20. The second width W2 is less than a width of each second side wall 90B of the second trench structure 20.

As described above, the SiC semiconductor device 1F includes the chip 2, the second trench structures 20 (trench structures), and the contact regions 50 of the p-type. The chip 2 includes the SiC monocrystal and has the first main surface 3. Each second trench structure 20 has the first side walls 90A and the second side walls 90B and is formed in the first main surface 3.

The first side walls 90A extend in the a-axis direction of the SiC monocrystal. The second side walls 90B extend in the m-axis direction of the SiC monocrystal. That is, the first side walls 90A are formed by m-planes of the SiC monocrystal and the second side walls 90B are formed by a-planes of the SiC monocrystal. Each contact region 50 is formed in a region inside the chip 2 along the corresponding second trench structure 20 at intervals in the m-axis direction from the first side walls 90A.

According to this structure, the m-plane defect (crystal defect) with the contact region 50 as the starting point can be suppressed in a region inside the chip 2 along the first side walls 90A. The SiC semiconductor device 1F that can be improved in electrical characteristics can thereby be provided. For example, by suppressing the m-plane defect with the contact region 50 as the starting point, a leak current due to the m-plane defect can be suppressed. For example, suppression of the m-plane defect is effective in terms of suppressing a zero gate voltage drain current IDSS due to the m-plane defect.

In another aspect, the SiC semiconductor device 1F may include the chip 2, the first semiconductor region 6 of the n-type, the body region 12 of the p-type, the second trench structures 20 as the trench source structures, the third trench structure 30 as the trench gate structure, the source regions 40 of the n-type, and the contact regions 50 of the p-type. The chip 2 includes the SiC monocrystal and has the first main surface 3. The first semiconductor region 6 is formed in the surface layer portion of the first main surface 3. The body region 12 is formed in the surface layer portion of the first semiconductor region 6.

Each second trench structure 20 has the first side walls 90A and the second side walls 90B and is formed in the first main surface 3. The first side walls 90A extend in the a-axis direction of the SiC monocrystal. The second side walls 90B extend in the m-axis direction of the SiC monocrystal. That is, the first side walls 90A are formed by m-planes of the SiC monocrystal and the second side walls 90B are formed by a-planes of the SiC monocrystal.

The third trench structure 30 is formed in the first main surface 3 at intervals in the m-axis direction from the first side walls 90A of the second trench structures 20 such as to penetrate through the body region 12. The source regions 40 are formed in the regions of the surface layer portion of the body region 12 along the third trench structure 30. The contact regions 50 are formed in regions inside the chip 2 along the second trench structures 20 at intervals in the m-axis direction from the first side walls 90A of the second trench structures 20.

According to this structure, the m-plane defect (crystal defect) with the contact region 50 as the starting point can be suppressed in regions between the second trench structures 20 and the third trench structure 30. The SiC semiconductor device 1F that can be improved in the electrical characteristics can thereby be provided. For example, by suppressing the m-plane defect with the contact region 50 as the starting point, the leak current due to the m-plane defect can be suppressed. For example, suppression of the m-plane defect is effective in terms of suppressing the zero gate voltage drain current IDSS due to the m-plane defect.

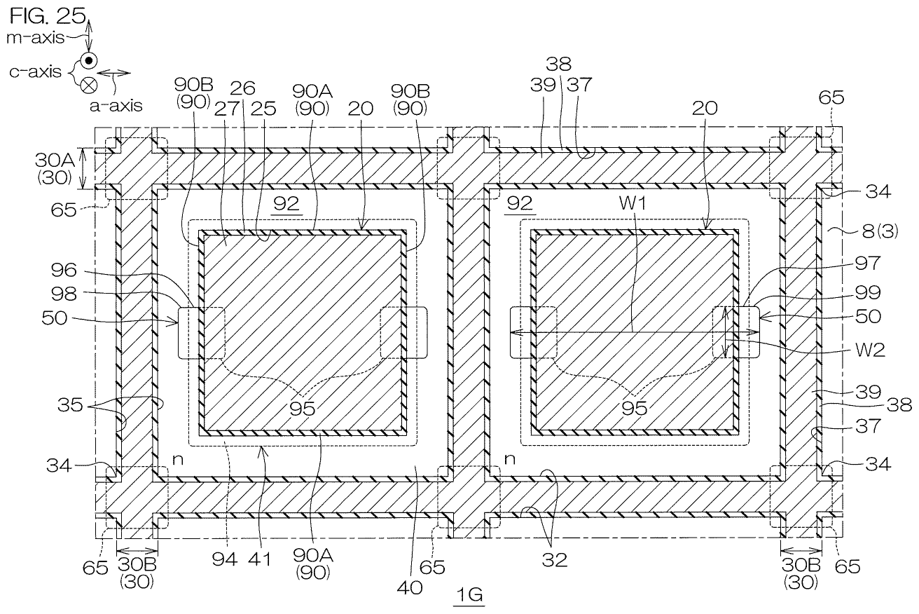

FIG. 25 is a plan view corresponding to FIG. 22 and showing an SiC semiconductor device 1G according to a seventh embodiment. The SiC semiconductor device 1G is a device that exhibits the same effects as the sic semiconductor device 1F. The contact regions 50 of the SiC semiconductor device 1F each include the bottom wall portion 95 extending in the band shape in the a-axis direction along the corresponding bottom wall 91 in plan view.

On the other hand, the SiC semiconductor device 1G has a structure with which a portion of the bottom wall portion 95 of the SiC semiconductor device 1F along the central portion of the bottom wall 91 is removed. That is, the bottom wall portion 95 of the SiC semiconductor device 1G has, at the central portion of the bottom wall 91, an open portion in which the well region 41 remains. With the SiC semiconductor device 1G, a formation region of the bottom wall portion 95 is reduced by the open portion. As a matter of course, the contact region 50 not having the bottom wall portion 95 may also be adopted.

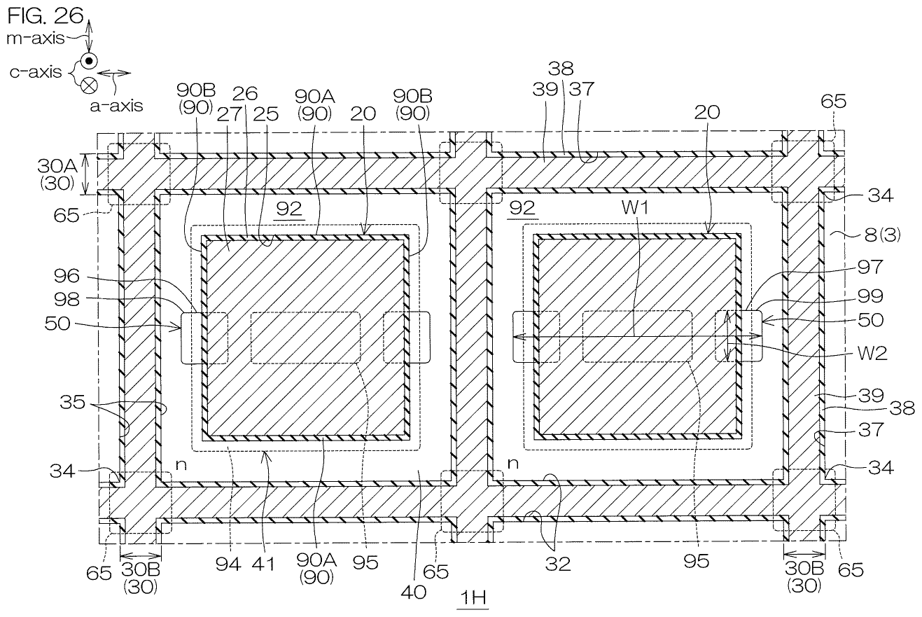

FIG. 26 is a plan view corresponding to FIG. 22 and showing an SiC semiconductor device 1H according to an eighth embodiment. The SiC semiconductor device 1H has a mode in which the contact regions 50 of the SiC semiconductor device 1G are modified and is a device that exhibits the same effects as the SiC semiconductor device 1H.

Specifically, each bottom wall portion 95 of the SiC semiconductor device 1H has a plurality of open portions. In this embodiment, the plurality of open portions are formed at intervals in the a-axis direction. As a matter of course, the plurality of open portions may be formed at intervals in the m-axis direction instead. Also, three or more open portions may be formed at intervals in the a-axis direction and the m-axis direction.

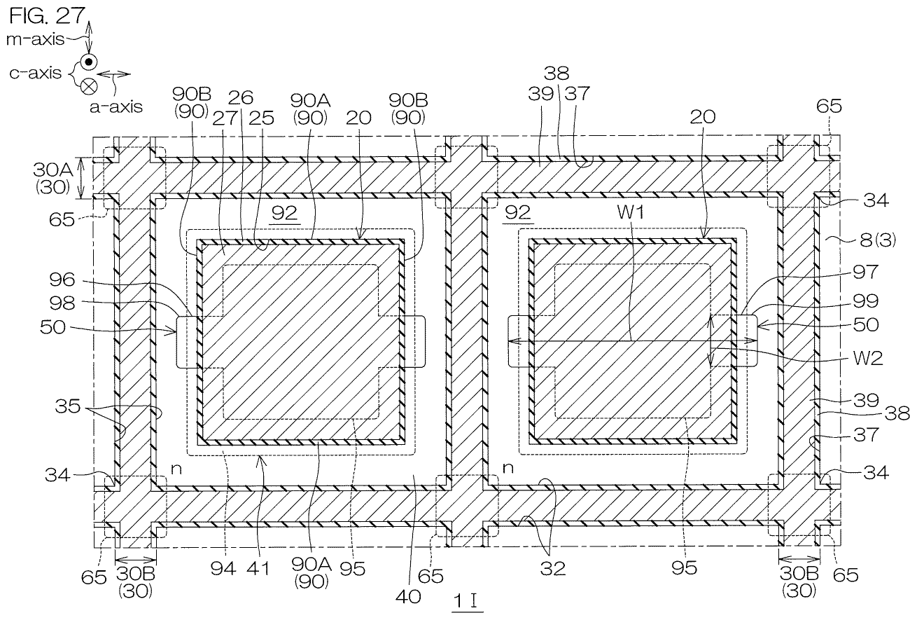

FIG. 27 is a plan view corresponding to FIG. 22 and showing an SiC semiconductor device 1I according to a ninth embodiment. The SiC semiconductor device 1I is a device that exhibits the same effects ast the Sic semiconductor device 1F. The SiC semiconductor device 1F described above includes the contact regions 50 each having the uniform second width W2 in the m-axis direction.

On the other hand, with each contact region 50 of the SiC semiconductor device 1I, the bottom wall portion 95 has a wide portion protruding toward either or both (in this embodiment, both) of the pair of first side walls 90A in plan view. The wide portion covers the bottom wall 91 at intervals in the m-axis direction from the pair of first side walls 90A. Also, the wide portion covers the bottom wall 91 at intervals in the a-axis direction from the pair of second side walls 90B. That is, a width of the wide portion exceeds the second width W2 but is less than the width of each second side wall 90B. The width of the wide portion may be not less than ½ the width of the second side wall 90B.

The bottom wall portion 95 preferably covers a region of not less than 50% but less than 100% of the bottom wall 91 in plan view. The above ratio (ratio of a planar area of the bottom wall portion 95 with respect to a planar area of the bottom wall 91) may be set to a value belonging to any one range among not less than 50% and not more than 60%, not less than 60% and not more than 70%, not less than 70% and not more than 80%, not less than 80% and not more than 90%, and not less than 90% but less than 100%.

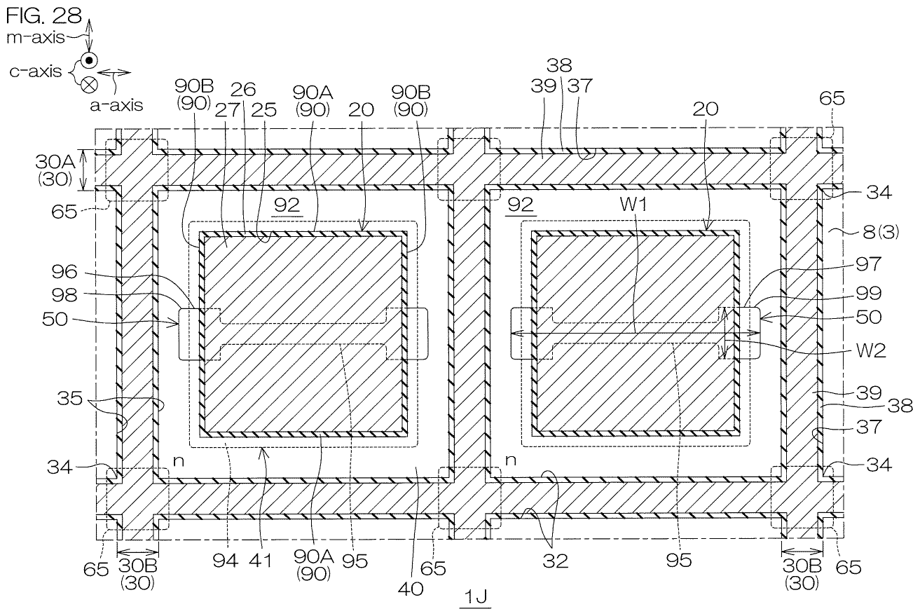

FIG. 28 is a plan view corresponding to FIG. 22 and showing an SiC semiconductor device 1J according to a tenth embodiment. The SiC semiconductor device 1J is a device that exhibits the same effects as the SiC semiconductor device 1F. The SiC semiconductor device 1F described above includes the contact regions 50 each having the uniform second width W2 in the m-axis direction.

On the other hand, with each contact region 50 of the SiC semiconductor device 1J, the bottom wall portion 95 has a narrow portion recessed toward either or both (in this embodiment, both) of the pair of first side walls 90A in plan view. A width of the narrow portion is less than the second width W2. The width of the narrow portion may be not more than ½ the second width W2. The width of the narrow portion may be not less than 1/10 the second width W2.

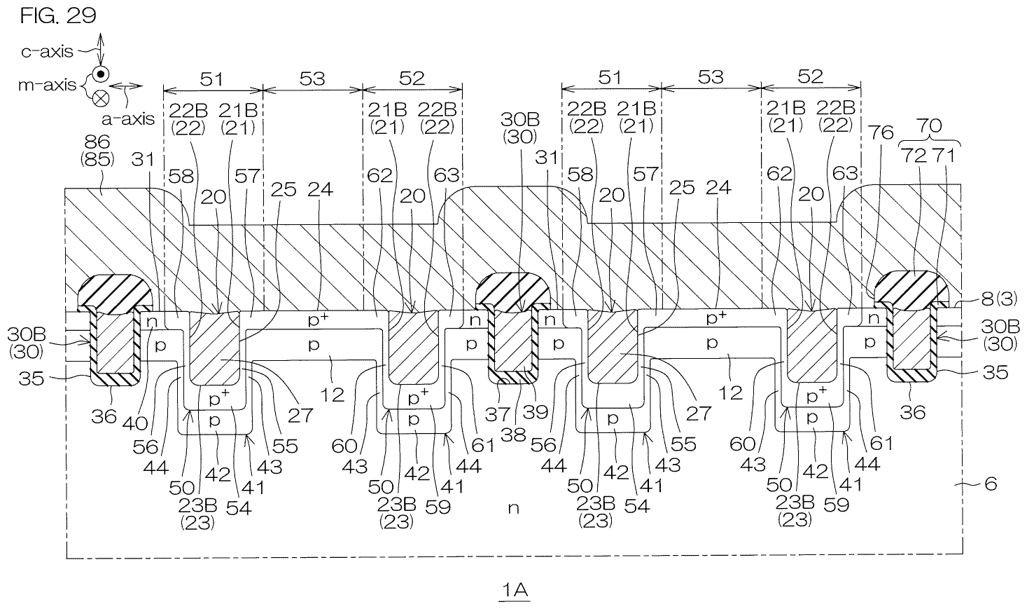

FIG. 29 is a cross sectional view showing a modification example of the second trench structures 20. Although an example in which the second trench structures 20 of the modification example are applied to the SiC semiconductor device 1A according to the first embodiment is shown in FIG. 29, the second trench structures 20 of the modification example may be applied to the SiC semiconductor devices 1B to 1F according to the second to sixth embodiments.

The second trench structures 20 of the respective embodiments described above each include the second trench 25, the second insulating film 26, and the second embedded electrode 27. On the other hand, the second trench structures 20 according to the modification example do not include the second insulating film 26. The second embedded electrode 27 is directly embedded in the second trench 25 and is electrically and mechanically connected to the chip 2 inside the second trench 25.

The source region 40, the well region 41, and the contact region 50 described above are electrically and mechanically connected to the second embedded electrode 27 at a portion along the wall surfaces (inner side wall 21, outer side wall 22, and bottom wall 23) of each second trench structure 20.

The second embedded electrodes 27 may each be formed using a portion of the source electrode 85 (source pad electrode 86). That is, the source electrode 85 (source pad electrode 86) may be formed such as to enter into the plurality of second trenches 25 from above the main surface insulating film 70 (active surface 8). In this case, the source electrode 85 (source pad electrode 86) includes a plurality of second embedded electrodes 27 that are electrically and mechanically connected to the chip 2 inside the plurality of second trenches 25.

Each of the embodiments described above can be implemented in yet other modes. With each of the embodiments described above, an example in which the second semiconductor region 7 is formed inside the chip 2 was illustrated. However, a structure not having the second semiconductor region 7 may be adopted. In this case, the first semiconductor region 6 is exposed from the first main surface 3, the second main surface 4, and the first to fourth side surfaces 5A to 5D of the chip 2. That is, the chip 2 may have a single layer structure not having an SiC substrate and consisting of just an SiC epitaxial layer.

In each of the embodiments described above, the regions of the “n-type” may be replaced with regions of the “p-type” at the same time as replacing the regions of the “p-type” with regions of the “n-type.” A specific configuration in this case can be obtained by replacing the “n-type” with the “p-type” at the same time as replacing the “p-type” with the “n-type” in the above descriptions and attached drawings. If the “p-type” is referred to as a “first conductivity type,” the “n-type” may be referred to as a “second conductivity type.” If the “n-type” is referred to as the “first conductivity type,” the “p-type” may be referred to as the “second conductivity type.”

With each of the embodiments described above, the second semiconductor region 7 of the “n-type” has been illustrated. However, the second semiconductor region 7 of the “p-type” may be adopted instead. In this case, an SiC-IGBT (insulated gate bipolar transistor) is formed instead of the SiC-MISFET. In this case, in the above description, the “source” of the MISFET is replaced with an “emitter” of the IGBT, and the “drain” of the MISFET is replaced with a “collector” of the IGBT. The second semiconductor region 7 of the “p-type” may consist of an SiC substrate of the “p-type” or may be formed by introducing a p-type impurity into a surface layer portion of the second main surface 4 of the chip 2 (epitaxial layer) by an ion implantation method.

Hereinafter, examples of features extracted from the present description and the attached drawings shall be indicated below. Hereinafter, the alphanumeric characters, etc., in parentheses represent the corresponding components, etc., in the embodiments described above, but are not intended to limit the scope of each clause to the embodiments. The “SiC semiconductor device” in the following clauses may be replaced with a “semiconductor device,” an “SiC semiconductor switching device,” or an “SiC-MISFET” as needed.

[A1] An SiC semiconductor device (1A to 1J) comprising: a chip (2) that includes an SiC monocrystal and has a main surface (3); a trench structure (20) that has a first side wall (22A, 90A) extending in an a-axis direction of the SiC monocrystal and a second side wall (22B, 90B) extending in an m-axis direction of the SiC monocrystal and is formed in the main surface (3); and a contact region (50) of a first conductivity type (p-type) that is formed in a region along the trench structure (20) at an interval in the m-axis direction from the first side wall (22A, 90A) inside the chip (2).

[A2] The SiC semiconductor device (1A to 1J) according to A1, wherein the trench structure has a bottom wall (23, 91) that connects the first side wall (22A, 90A) and the second side wall (22B, 90B), and the contact region (50) is formed in a region along the bottom wall (23, 91) of the trench structure (20) inside the chip (2).

[A3] The SiC semiconductor device (1A to 1J) according to A1 or A2, wherein the contact region (50) is formed in a region along the second side wall (22B, 90B) of the trench structure (20) inside the chip (2).

[A4] The SiC semiconductor device (1A to 1J) according to any one of A1 to A3, wherein the contact region (50) is formed in a band shape extending in the a-axis direction.

[A5] The SiC semiconductor device (1A to 1J) according to any one of A1 to A4, wherein the contact region (50) has a first width (W1, Wa) in the a-axis direction and has a second width (W2, Wb), less than the first width (W1, Wa), in the m-axis direction.

[A6] The SiC semiconductor device (1A to 1J) according to A5, wherein the second width (W2, Wb) is less than a width of the second side wall (22B, 90B).

[A7] The SiC semiconductor device (1A to 1J) according to A5 or A6, wherein the first width (W1, Wa) is not less than a width of the first side wall (22A, 90A).

[A8] The SiC semiconductor device (1A to 1J) according to any one of A1 to A7, further comprising: a well region (41) of the first conductivity type (p-type) that is formed in a region along the first side wall (22A, 90A) inside the chip (2); and wherein the contact region (50) has a higher impurity concentration than the well region (41).

[A9] The SiC semiconductor device (1A to 1J) according to A8, wherein the well region (41) is formed in a region along the trench structure (20) and the contact region (50) is formed inside the well region (41) inside the chip (2).

[A10] The SiC semiconductor device (1A to 1J) according to any one of A1 to A9, further comprising: a body region (12) of the first conductivity type (p-type) that is formed in a surface layer portion of the main surface (3); and wherein the trench structure (20) is formed in the main surface (3) such as to penetrate through the body region (12), and the contact region (50) has a higher impurity concentration than the body region (12).

[A11] The SiC semiconductor device (1A to 1J) according to any one of A1 to A10, wherein the trench structure (20) is formed in an annular shape in plan view.

[A12] The SiC semiconductor device (1A to 1J) according to A11, further comprising: a mesa portion (24) that is demarcated in the main surface (3) by the trench structure (20); and wherein the contact region (50) has a portion positioned in a surface layer portion of the main surface (3) in the mesa portion (24).

[A13] The SiC semiconductor device (1A to 1J) according to any one of A1 to A12, wherein the trench structure (20) is formed in a quadrangle shape in plan view.

[A14] The SiC semiconductor device (1A to 1J) according to any one of A1 to A13, wherein a source potential is applied to the trench structure (20).

[A15] The SiC semiconductor device (1A to 1J) according to any one of A1 to A14, further comprising: a second trench structure (30) that is formed in the main surface (3) at an interval from the trench structure (20) and to which a gate potential is applied.

[A16] The SiC semiconductor device (1A to 1J) according to A15, wherein the second trench structure (30) is formed in the main surface (3) at an interval in the m-axis direction from the first side wall (22A, 90A) of the trench structure (20) and extends in the a-axis direction.

[A17] The SiC semiconductor device (1A to 1J) according to A15 or A16, wherein the second trench structure (30) is formed in the main surface (3) at an interval in the a-axis direction from the second side wall (22B, 90B) of the trench structure (20) and extends in the m-axis direction.

[A18] The SiC semiconductor device (1A to 1J) according to any one of A15 to A17, wherein the second trench structure (30) is formed in an annular shape surrounding the trench structure (20) in plan view.

[A19] The SiC semiconductor device (1A to 1J) according to any one of A15 to A18, further comprising: a source region (40) of a second conductivity type (n-type) that is formed in a region along the second trench structure (30) in a surface layer portion of the main surface (3).

[A20] An SiC semiconductor device (1A to 1J) comprising: a chip (2) that includes an SiC monocrystal and has a main surface (3); a semiconductor region (6) of a first conductivity type (n-type) that is formed in a surface layer portion of the main surface (3); a body region (12) of a second conductivity type (p-type) that is formed in a surface layer portion of the semiconductor region (6); a trench source structure (20) that has a first side wall (22A, 90A) extending in an a-axis direction of the SiC monocrystal and a second side wall (22B, 90B) extending in an m-axis direction of the SiC monocrystal and is formed in the main surface (3) such as to penetrate through the body region (12); a trench gate structure (30) that is formed in the main surface (3) at an interval in the m-axis direction from the first side wall (22A, 90A) of the trench source structure (20) such as to penetrate through the body region (12); a source region (40) of the first conductivity type (n-type) that is formed in a region along the trench gate structure (30) in a surface layer portion of the body region (12); and a contact region (50) of the second conductivity type (p-type) that is formed in a region along the trench source structure (20) at an interval in the m-axis direction from the first side wall (22A, 90A) of the trench source structure (20) inside the chip (2).

While embodiments of the present invention have been described in detail above, those are merely specific examples used to clarify the technical contents. The various technical ideas extracted from this Description are not limited by the order of description, the order of the embodiments, etc., in the Description and can be combined as appropriate with each other.

What is claimed is:

1. An SiC semiconductor device comprising:
a chip that includes an SiC monocrystal and has a main surface;
a trench structure that has a first side wall extending in an a-axis direction of the SiC monocrystal and a second side wall extending in an m-axis direction of the SiC monocrystal and is formed in the main surface; and
a contact region of a first conductivity type that is formed in a region along the trench structure at an interval in the m-axis direction from the first side wall inside the chip.

2. The SiC semiconductor device according to claim 1,
wherein the trench structure has a bottom wall that connects the first side wall and the second side wall, and
the contact region is formed in a region along the bottom wall of the trench structure inside the chip.

3. The SiC semiconductor device according to claim 1,
wherein the contact region is formed in a region along the second side wall of the trench structure inside the chip.

4. The SiC semiconductor device according to claim 1,
wherein the contact region is formed in a band shape extending in the a-axis direction.

5. The SiC semiconductor device according to claim 1,
wherein the contact region has a first width in the a-axis direction and has a second width, less than the first width, in the m-axis direction.

6. The SiC semiconductor device according to claim 5,
wherein the second width is less than a width of the second side wall.

7. The SiC semiconductor device according to claim 5,
wherein the first width is not less than a width of the first side wall.

8. The SiC semiconductor device according to claim 1, further comprising:
a well region of the first conductivity type that is formed in a region along the first side wall inside the chip; and
wherein the contact region has a higher impurity concentration than the well region.

9. The SiC semiconductor device according to claim 8,
wherein the well region is formed in a region along the trench structure inside the chip, and
the contact region is formed inside the well region.

10. The SiC semiconductor device according to claim 1, further comprising:
a body region of the first conductivity type that is formed in a surface layer portion of the main surface; and
wherein the trench structure is formed in the main surface such as to penetrate through the body region, and
the contact region has a higher impurity concentration than the body region.

11. The SiC semiconductor device according to claim 1,
wherein the trench structure is formed in an annular shape in plan view.

12. The SiC semiconductor device according to claim 11, further comprising:
a mesa portion that is demarcated in the main surface by the trench structure; and
wherein the contact region has a portion positioned in a surface layer portion of the main surface in the mesa portion.

13. The SiC semiconductor device according to claim 1,
wherein the trench structure is formed in a quadrangle shape in plan view.

14. The SiC semiconductor device according to claim 1,
wherein a source potential is applied to the trench structure.

15. The SiC semiconductor device according to claim 1, further comprising:
a second trench structure that is formed in the main surface at an interval from the trench structure and to which a gate potential is applied.

16. The SiC semiconductor device according to claim 15,
wherein the second trench structure is formed in the main surface at an interval in the m-axis direction from the first side wall of the trench structure and extends in the a-axis direction.

17. The SiC semiconductor device according to claim 15,
wherein the second trench structure is formed in the main surface at an interval in the a-axis direction from the second side wall of the trench structure and extends in the m-axis direction.

18. The SiC semiconductor device according to claim 15,
wherein the second trench structure is formed in an annular shape surrounding the trench structure in plan view.

19. The SiC semiconductor device according to claim 15, further comprising:
a source region of a second conductivity type that is formed in a region along the second trench structure in a surface layer portion of the main surface.

20. An SiC semiconductor device comprising:
a chip that includes an SiC monocrystal and has a main surface;
a semiconductor region of a first conductivity type that is formed in a surface layer portion of the main surface;
a body region of a second conductivity type that is formed in a surface layer portion of the semiconductor region;
a trench source structure that has a first side wall extending in an a-axis direction of the SiC monocrystal and a second side wall extending in an m-axis direction of the SiC monocrystal and is formed in the main surface such as to penetrate through the body region;
a trench gate structure that is formed in the main surface at an interval in the m-axis direction from the first side wall of the trench source structure such as to penetrate through the body region;
a source region of the first conductivity type that is formed in a region along the trench gate structure in a surface layer portion of the body region; and
a contact region of the second conductivity type that is formed in a region along the trench source structure at an interval in the m-axis direction from the first side wall of the trench source structure inside the chip.
